(19) United States
(12) Patent Application Publication
(10) Pub. No.: US 2026/0182140 A1
(43) Pub. Date: Jun. 25, 2026

(54) Display Device

(71) Applicant: LG Display Co., Ltd., Seoul (KR)

(72) Inventors: Hyunsook Jeon, Paju-si (KR); Sohee Lee, Paju-si (KR); YongCheol Kim, Paju-si (KR)

(21) Appl. No.: 19/361,424

(22) Filed: Oct. 17, 2025

(30) Foreign Application Priority Data
Dec. 24, 2024 (KR) 10-2024-0195693

(51) Int. Cl. H10K 50/15; H10K 50/11; H10K 50/18; H10K 59/65; H10K 101/40

(52) U.S. Cl. CPC H10K 50/156; H10K 50/11; H10K 50/181; H10K 59/65; H10K 2101/40

(57) ABSTRACT

The present disclosure provides a display device that includes a plurality of light emitting elements disposed on a substrate, and is capable of preventing or reducing malfunction of an optical sensor by including a structure where at least one of the plurality of light emitting elements comprises a first electrode disposed on the substrate, a hole transport layer disposed on the first electrode, an electron blocking layer disposed on the hole transport layer, an emission layer disposed on the electron blocking layer and having a width greater than the electron blocking layer, and a second electrode disposed on the emission layer.

### CROSS REFERENCE TO RELATED APPLICATION

This application claims priority under 35 U.S.C. § 119(a) to the Republic of Korea Patent Application No. 10-2024-0195693, filed on Dec. 24, 2024, the entire contents of which are hereby expressly incorporated by reference into the present application.

### TECHNICAL FIELD

The present disclosure relates to electronic devices, and more specifically, to display devices.

### BACKGROUND

As display technology has advanced, display devices have been developed to provide increased functions, such as an image capture function, a sensing function, and the like, as well as an image display function. To provide these functions, display devices have been equipped with optical electronic devices, such as a camera, a sensor for detecting an image, a sensor for detecting light, a light receiving device, and the like.

To effectively receive light passing through the front surface of a display device, it may be desirable for such an optical electronic device to be located in an area of the display device where incident light coming through the front surface can be increasingly received and detected. Taking account of this issue, typical display devices have employed a structure in which an optical electronic device is located in a front portion of the display devices to allow the optical electronic device to be effectively exposed to incident light. To install such an optical electronic device such as a camera, a sensor, and the like in a display device in this structure, a bezel of the display device may be increased, or a notch or a hole for accommodating the optical electronic device may be needed to be formed in a display area of a display panel.

According to this configuration, as an optical electronic device such as a camera, a sensor, and the like for receiving or detecting light being incident through the front surface and performing an intended function is included in a display device, the size of a bezel in the front of the display device may be increased, or a substantial limitation may be imposed on designing a front portion of the display device.

### SUMMARY

To address these issues, one or more aspects of the present disclosure may provide a display device that includes a light transmissive structure capable of enabling at least one optical electronic device disposed under, or at a lower portion of, a display panel to normally receive light (e.g., visible light, infrared light, ultraviolet light, or the like) while not being exposed in the front of the display device.

One or more aspects of the present disclosure may provide a display device that includes a structure in which at least one optical electronic device is disposed to be overlapped with a display area of a display panel while being located under the display area, and is capable of enabling a full-screen display to be implemented by using all of the display area as a display screen.

One or more aspects of the present disclosure may provide a display device that includes a structure where a hole movement path is formed in a light emitting element, and is capable of preventing or reducing the presence of residual light.

One or more aspects of the present disclosure may provide a display device that includes a structure where a hole movement path is formed in a light emitting element, and is capable of preventing or reducing malfunction of one or more optical sensors.

One or more aspects of the present disclosure may provide a display device that includes a structure where a hole movement path is formed in a light emitting element, and is capable of improving the sensing efficiency of one or more optical sensors by external light.

One or more aspects of the present disclosure may provide a display device capable of improving the reliability of light emitting elements by reducing the degradation of luminance in a display area and the reduction of lifetime of the light emitting elements.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a plurality of light emitting elements disposed on a substrate. In one or more aspects, at least one of the plurality of light emitting elements may include a first electrode disposed on the substrate, a hole transport layer disposed on the first electrode, an electron blocking layer disposed on the hole transport layer, an emission layer disposed on the electron blocking layer and having a width greater than the electron blocking layer, and a second electrode disposed on the emission layer.

According to one or more aspects of the present disclosure, a display device may be provided that includes a light transmissive structure capable of enabling at least one optical electronic device disposed under, or at a lower portion of, a display panel to normally receive light (e.g., visible light, infrared light, ultraviolet light, or the like) while not being exposed in the front of the display device.

According to one or more aspects of the present disclosure, a display device may be provided that is capable of enabling a full-screen display to be implemented by using a whole display area of a display panel as a display screen by including a structure at least one optical electronic device is disposed to be overlapped with the display area while being located under the display area.

According to one or more aspects of the present disclosure, a display device may be provided that is capable of preventing or reducing the presence of residual light by including a structure where a hole movement path is formed in a light emitting element.

According to one or more aspects of the present disclosure, a display device may be provided that is capable of preventing or reducing malfunction of one or more optical sensors by including a structure where a hole movement path is formed in a light emitting element.

According to one or more aspects of the present disclosure, a display device may be provided that is capable of improving the sensing efficiency of one or more optical sensors by external light by including a structure where a hole movement path is formed in a light emitting element.

According to one or more aspects of the present disclosure, a display device may be provided that is capable of improving the reliability of light emitting elements by reducing the degradation of luminance in a display area and the reduction of lifetime of the light emitting elements.

According to one or more aspects of the present disclosure, a display device may be provided that is capable of enabling high efficiency, improving lifetime and consuming low power by reducing the degradation of luminance in a display area and the reduction of lifetime of light emitting elements.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example configuration of a display device according to aspects of the present disclosure.

FIG. 2 illustrates an example system configuration of the display device according to aspects of the present disclosure.

FIG. 3 illustrates an example configuration of a display panel according to aspects of the present disclosure.

FIG. 4 illustrates the configuration of example three areas included in a display area of the display device according to aspects of the present disclosure.

FIG. 5 illustrates an example cross-sectional view of an optical area defined in the display panel according to aspects of the present disclosure.

FIG. 6 illustrates an example cross-sectional view of a normal light emitting element.

FIG. 7 is an example cross-sectional view and energy band diagram for a normal light emitting element.

FIG. 8 is an example cross-sectional view of a normal display device to which the light emitting element illustrated in FIG. 7 is applied.

FIG. 9 is an example cross-sectional view and energy band diagram for a light emitting element according to aspects of the present disclosure.

FIG. 10 is an example cross-sectional view of the display device to which the light emitting element illustrated in FIG. 9 is applied.

FIG. 11 is an example cross-sectional view for comparing a light emitting element according to aspects of the present disclosure with a normal light emitting element.

FIG. 12 is an example cross-sectional view and energy band diagram for a light emitting element according to aspects of the present disclosure.

FIG. 13 is an example cross-sectional view of the display device to which the light emitting element illustrated in FIG. 12 is applied.

FIG. 14 is an example cross-sectional view and energy band diagram for a light emitting element according to aspects of the present disclosure.

FIG. 15 is an example cross-sectional view of the display device to which the light emitting element illustrated in FIG. 14 is applied.

FIG. 16 is an example cross-sectional view for comparing a light emitting element according to aspects of the present disclosure with a normal light emitting element.

FIG. 17 is another example cross-sectional view of the display device to which the light emitting element illustrated in FIG. 14 is applied.

FIG. 18 is a graph illustrating example characteristics of luminance and turn-off in the display device according to aspects of the present disclosure and a normal display device.

FIG. 19 is a graph illustrating example characteristics of luminance and turn-off in the display device according to aspects of the present disclosure and a normal display device.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

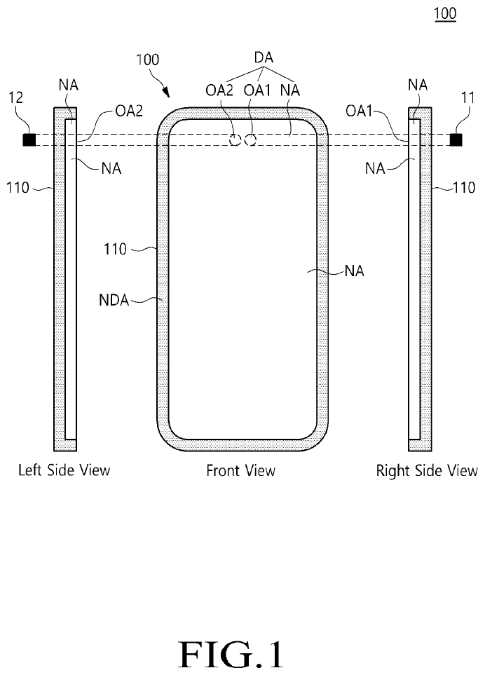

FIG. 1 illustrates an example configuration of a display device 100 according to aspects of the present disclosure.

Referring to FIG. 1, in one or more example embodiments, the display device 100 may include a display panel 110 for displaying an image, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA in which one or more images can be displayed and a non-display area NDA in which an image is not displayed.

A plurality of subpixels may be disposed in the display area DA, and several types of signal lines for driving the plurality of subpixels may be disposed therein.

The non-display area NDA may represent an area outside of the display area DA or an area around an outer edge of the display area DA. Several types of signal lines may be disposed in the non-display area NDA, and several types of driving circuits may be connected to, or located in the non-display area NDA. At least a portion of the non-display area NDA may be bent, and thereby, be invisible from the front surface of the display device 100 or be covered by a case or housing (not shown) of the display device 100. The non-display area NDA may be also referred to as a non-active area, a bezel, or a bezel area.

Referring to FIG. 1, in one or more aspects, the one or more optical electronic devices (11 and/or 12) may be prepared as separate devices from the display panel 110 and thereafter included in the display device 100. For example, the one or more optical electronic devices (11 and/or 12) may be located under, or at a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or at the lower portion of, the display panel 110 (the opposite side of the viewing surface). Light passing through the display panel 110 may include, for example, visible light, ultraviolet light, or the like.

The one or more optical electronic devices (11 and/or 12) may be devices capable of receiving or detecting light passing through the display panel 110 and perform a predefined function based on the received light. For example, the one or more optical electronic devices (11 and/or 12) may include one or more of the following: an image capture device such as a camera, an image sensor, and/or the like; or a sensor such as a proximity sensor, an illuminance sensor, and/or the like. For example, the sensor may be an infrared sensor capable of performing a predetermined operation using infrared light.

Referring to FIG. 1, in one or more aspects, the display area DA of the display panel 110 may include one or more optical areas (OA1 and/or OA2) and a normal area NA. Herein, the term “normal area” NA may be an area that while being present in the display area DA, does not overlap with one or more optical electronic devices (11 and/or 12) and may also be referred to as a non-optical area. The one or more optical areas (OA1 and/or OA2) may be one or more areas respectively overlapping with the one or more optical electronic devices (11 and/or 12) in a cross-sectional view of the display panel 110.

In one or more aspects, although FIG. 1 illustrates a structure where the display device 100 includes two optical areas (OA1, OA2), aspects of the present disclosure are not limited thereto. For example, the display device 100 may include one first optical area (OA1 or OA2) and a normal area NA. In these configurations, at least a portion of the first optical area OA1 may overlap with a first optical electronic device 11.

In one or more aspects, the one or more optical areas (OA1 and/or OA2) may be desired to include both an image display structure and a light transmissive structure. For example, since the one or more optical areas (OA1 and/or OA2) are included in the display area DA, corresponding light emitting areas of subpixels for displaying images may be desired to be disposed in the one or more optical areas (OA1 and/or OA2). Further, to enable the one or more optical electronic devices (11 and/or 12) to fully receive light, the one or more optical areas (OA1 and/or OA2) may be desirable to include a light transmissive structure.

Hereinafter, for convenience of description, discussions are provided based on examples where the first optical electronic device 11 is a camera, and the second optical electronic device 12 is a sensor. It should be, however, understood that the scope of the present disclosure includes examples where the first optical electronic device 11 is the sensor, and the second optical electronic device 12 is the camera. The camera may be, for example, a camera lens, an image sensor, or a unit including at least one of the camera lens and the image sensor.

The normal area NA and the one or more optical areas (OA1 and/or OA2) included in the display area DA may be areas where an image can be displayed. It should be noted here that the normal area NA may be an area in which a light transmissive structure need not be implemented, and the one or more optical areas (OA1 and/or OA2) may be areas in which a light transmissive structure is needed to be implemented.

Accordingly, the one or more optical areas (OA1 and/or OA2) may have a transmittance greater than or equal to a predetermined level, i.e., a relatively high transmittance, and the normal area NA may have a transmittance less than the predetermined level or not have light transmittance.

For example, the one or more optical areas (OA1 and/or OA2) may have a resolution, a subpixel arrangement structure, the number of subpixels per unit area, an electrode structure, a line structure, an electrode arrangement structure, a line arrangement structure, or/and the like different from that/those of the normal area NA.

In one or more aspects, the number of subpixels per unit area in the one or more optical areas (OA1 and/or OA2) may be less than the number of subpixels per unit area in the normal area NA. For example, the resolution of the one or more optical areas (OA1 and/or OA2) may be lower than that of the normal area NA. Here, the number of subpixels per unit area may mean the same as resolution, density of pixels, or integration degree of pixels. For example, the number of subpixels per unit area may be represented as pixels per inch (PPI), which represents the number of pixels in one inch.

The first optical area OA1 may have various shapes, such as a circle, an ellipse, a quadrangle, a hexagon, an octagon or the like. The second optical area OA2 may have various shapes, such as a circle, an ellipse, a quadrangle, a hexagon, an octagon or the like. The first optical area OA1 and the second optical area OA2 may have the same or substantially or nearly the same shape, or different shapes. Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape.

Herein, the display device 100 having a structure in which the first optical electronic device 11 such as a camera, and the like, is located under, or at a lower portion of, the display panel 110 without being exposed to the outside may be referred to as a display in which under-display camera (UDC) technology is implemented.

According to this structure, the display device 100 can provide an advantage of preventing a size of the display area DA from being reduced because a notch or a camera hole for exposing a camera need not be formed in the display panel 110. Indeed, since a notch or a camera hole for camera exposure need not be formed in the display panel 110, the display device 100 can provide further advantages of reducing a size of a bezel area, and improving the degree of freedom in design because such limitations to the design are removed.

Herein, the display device 100 having a structure in which the second electronic device 12, for example, a sensor such as a proximity sensor, an illuminance sensor, an infrared sensor, or the like is located under, or at a lower portion of, the display panel 110 without being exposed to the outside may be referred to as a display to which under-display infrared (UDIR) technology is applied.

Although the one or more optical electronic devices (11 and/or 12) are located under, or at a lower portion of, the display panel 110 of the display device 100 (e.g., hidden or not exposed to the outside), the one or more optical electronic devices (11 and/or 12) are needed to normally receive or detect light, and thereby, perform predefined functionalities.

Further, although the one or more optical electronic devices (11 and/or 12) in the display device 100 are located under, or at a lower portion of, the display panel 110 to be hidden and located to be overlapped with the display area DA, it is necessary for image display to be normally performed in the one or more optical areas (OA1 and/or OA2) overlapping with the one or more optical electronic devices (11 and/or 12) in the display area DA. Thus, in one or more aspects, even though one or more optical electronic devices (11 and/or 12) are located on the back of the display panel, images can be displayed in a normal manner (e.g., without a reduction in image quality) in the one or more optical areas (OA1 and/or OA2) overlapping with the one or more optical electronic devices (11 and/or 12) in the display area DA.

It should be understood that as the first optical area OA1 is designed as a transparent area, image display characteristics in the first optical area OA1 may be different from image display characteristics in the normal area NA.

Further, when the first optical area OA1 is designed to improve image display characteristics, the transmittance of the first optical area OA1 may decrease.

To address these issues, in one or more aspects, the display device can be provided that includes a structure of the first optical area OA1 in which the light transmittance of the first optical area OA1 can be improved without causing a difference in image quality between the first optical area OA1 and the normal area NA.

Further, in one or more aspects, the display device can be provided that includes a structure of the second optical area OA2 in which the image quality and light transmittance of second optical area OA2 can be improved.

Further, in one or more aspects, while the first optical area OA1 and the second optical area OA2 included in the display device 100 are light transmissive areas having similar functions, the first optical area OA1 and the second optical area OA2 may be used in different applications. Therefore, the first optical area OA1 and the second optical area OA2 included in the display device 100 may be designed to have different structures from each other.

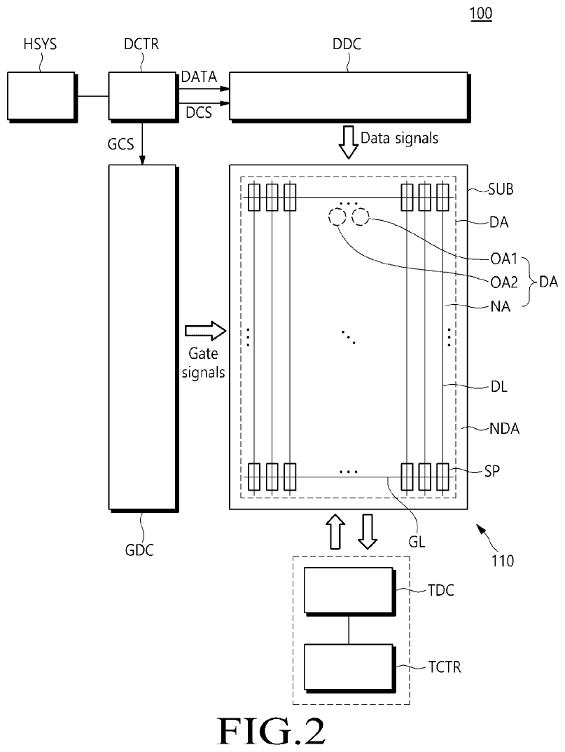

FIG. 2 illustrates an example system configuration of the display device 100 according to aspects of the present disclosure. In discussions that follow for the configuration of FIG. 2, discussions for features and configurations equal, substantially equal, or similar to the features and configurations described with reference to FIG. 1 are omitted or briefly described for conciseness.

Referring to FIG. 2, in one or more example embodiments, the display device 100 may include the display panel 110 and at least one display driving circuit as components for displaying one or more images.

The display driving circuit may be a circuit for driving the display panel 110, and include a data driving circuit DDC, a gate driving circuit GDC, a display controller DTCR, and other circuit components.

The display panel 110 may include a substrate SUB and a plurality of subpixels SP disposed on the substrate SUB. The display panel 110 may further include several types of signal lines to drive the plurality of subpixels SP.

In one or more aspects, the display device 100 herein may be a liquid crystal display device, or the like, or a self-emissive display device in which light is emitted from the display panel 110 itself. In an example where the display device 100 is the self-emissive display device, each of a plurality of subpixels SP included in the display panel 110 may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In a further embodiment, the display device 100 according to aspects of the present disclosure may be a quantum dot display device in which the light emitting element is implemented using quantum dots, which are self-emission semiconductor crystals.

The structure of each of the plurality of subpixels SP may be differently configured or designed according to types of the display device 100. For example, in an example where the display device 100 is a self-emissive display device including self-emissive subpixels SP, each subpixel SP may include a self-emissive light emitting element, one or more transistors, and one or more capacitors.

In one or more aspects, several types of signal lines disposed in the display device 100 may include, for example, a plurality of data lines DL for delivering data signals (which may be referred to as data voltages or image signals), a plurality of gate lines GL for delivering gate signals (which may be referred to as scan signals), and the like.

The plurality of data lines DL and the plurality of gate lines GL may intersect each other. Each of the plurality of data lines DL may extend in a first direction. Each of the plurality of gate lines GL may extend in a second direction different from the first direction. For example, the first direction may be the column or vertical direction, and the second direction may be the row or horizontal direction. In another example, the first direction may be the row or horizontal direction, and the second direction may be the column or vertical direction.

The data driving circuit DDC may be a circuit for driving the plurality of data lines DL, and can supply data signals to the plurality of data lines DL. The gate driving circuit GDC may be a circuit for driving the plurality of gate lines GL, and can supply gate signals to the plurality of gate lines GL.

The display controller DCTR may be a device for controlling the data driving circuit DDC and the gate driving circuit GDC, and can control driving times for the plurality of data lines DL and driving times for the plurality of gate lines GL.

The display controller DCTR can supply a data driving control signal DCS to the data driving circuit DDC to control the data driving circuit DDC, and supply a gate driving control signal GCS to the gate driving circuit GDC to control the gate driving circuit GDC.

The display controller DCTR can receive input image data from a host system HSYS and supply image data DATA readable by the data driving circuit DDC based on the input image data to the data driving circuit DDC.

The data driving circuit DDC can receive digital image data DATA from the display controller DCTR, convert the received image data DATA into analog data signals, and output the resulting analog data signals to the plurality of data lines DL.

The gate driving circuit GDC can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit DDC may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more aspects, the gate driving circuit GDC may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more aspects, the gate driving circuit GDC may be disposed in the non-active area NDA of the display panel 110 by a gate-in-panel (GIP) technique. The gate driving circuit GDC may be disposed on the substrate, or connected to the substrate. In an example where the gate driving circuit GDC is implemented by the GIP technique, the gate driving circuit GDC may be disposed in the non-display area NDA of the substrate. The gate driving circuit GDC may be connected to the substrate in an example where the gate driving circuit GDC is implemented by the chip-on-glass (COG) technique, the chip-on-film (COF) technique, or the like.

In one or more aspects, at least one of the data driving circuit DDC and the gate driving circuit GDC may be disposed in the display area DA of the display panel 110. For example, at least one of the data driving circuit DDC and the gate driving circuit GDC may be disposed not to overlap with subpixels SP, or disposed to overlap with one or more, or all, of the subpixels SP, or at least respective one or more portions of one or more subpixels SP.

In one or more aspects, the data driving circuit DDC may be disposed in, and/or electrically connected to, but not limited to, only one side or edge (e.g., an upper portion or a lower portion) of the display panel 110. In one or more aspects, the data driving circuit DDC may be located in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

In one or more aspects, the gate driving circuit GDC may be located in, and/or electrically connected to, but not limited to, one side or edge (e.g., a left portion or a right portion) of the display panel 110. In one or more aspects, the gate driving circuit GDC may be located in, and/or electrically connected to, but not limited to, two sides or edges (e.g., a left portion and a right portion) of the panel 110 or at least two of four sides or edges (e.g., an upper portion, a lower portion, the left portion, and the right portion) of the panel 110 according to driving schemes, panel design schemes, or the like.

The display controller DCTR may be implemented in a separate component from the data driving circuit DDC, or integrated with the data driving circuit DDC, so that the display controller DCTR and the data driving circuit DDC can be implemented in a single integrated circuit.

The display controller DCTR may be a timing controller used in the normal display technology or a controller or a control device capable of performing other control functions in addition to the function of the normal timing controller. In one or more aspects, the display controller DCTR may be a controller or a control device different from the timing controller, or a circuitry or a component included in the controller or the control device. The display controller DCTR may be implemented with various circuits or electronic components such as an integrated circuit (IC), a field programmable gate array (FPGA), an application specific integrated circuit (ASIC), a processor, and/or the like.

The display controller DCTR may be mounted on a printed circuit board, a flexible printed circuit, or the like, and may be electrically connected to the data driving circuit DDC and the gate driving circuit GDC through the printed circuit board, the flexible printed circuit, and/or the like.

The display controller DCTR can transmit signals to, and receive signals from, the data driving circuit DDC via one or more predefined interfaces. For example, such interfaces may include a low voltage differential signaling (LVDS), an embedded clock point-point interface (EPI), a serial peripheral interface (SPI), and the like.

In one or more aspects, to further provide a touch sensing function as well as an image display function, the display device 100 may include at least one touch sensor, and a touch sensing circuit capable of detecting whether a touch event occurs by a touch object such as a finger, a pen, or the like, or of detecting a corresponding touch position, by sensing the touch sensor.

The touch sensing circuit may include a touch driving circuit TDC capable of generating and providing touch sensing data by driving and sensing the touch sensor, a touch controller TCTR capable of detecting the occurrence of a touch event or detecting a touch position (or touch coordinates) using the touch sensing data, and one or more other components.

The touch sensor may include a plurality of touch electrodes. The touch sensor may further include a plurality of touch lines for electrically connecting the plurality of touch electrodes to the touch driving circuit TDC.

The touch sensor may be disposed outside of the display panel 110 in the form of a touch panel or may be disposed inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit TDC can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrodes and an object such as a finger, a pen, and/or the like. According to the self-capacitance sensing technique, each of a plurality of touch electrodes can serve as both a driving touch electrode and a sensing touch electrode. The touch driving circuit TDC can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit TDC can drive the driving touch electrodes and sense the sensing touch electrodes.

In one or more aspects, the touch driving circuit TDC and the touch controller TCTR, which are included in the touch sensing circuit, may be implemented in separate devices or in one device. In one or more aspects, the touch driving circuit TDC and the data driving circuit DDC may be implemented in separate devices or in one device.

The display device 100 may further include a power supply circuit for supplying several types of power to the display driving circuit and/or the touch sensing circuit.

In one or more aspects, the display device 100 may be a mobile terminal such as a smart phone, a tablet, or the like, or a monitor, a television (TV), or the like. Further, the display device 100 may be configured with various types, sizes, and shapes to display information or images. For example, the display device 100 may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

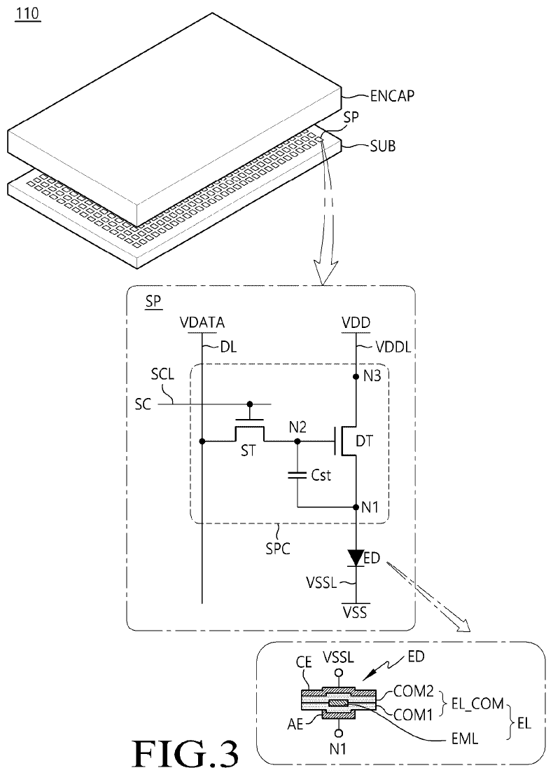

FIG. 3 illustrates an example configuration of the display panel 110 according to aspects of the present disclosure. In discussions that follow for the configuration of FIG. 3, discussions for features and configurations equal, substantially equal, or similar to the features and configurations described with reference to FIGS. 1 and 2 are omitted or briefly described for simplicity.

Referring to FIG. 3, the display panel 110 may include a substrate SUB on which a plurality of subpixels SP are disposed, and an encapsulation layer ENCAP over the substrate SUB. The encapsulation layer ENCAP may also be referred to as an encapsulation substrate or an encapsulation part.

Referring to FIG. 3, in one or more example embodiments, when the display device 100 (FIG. 1) is a self-emissive display device, each of the plurality of subpixels SP disposed on the substrate SUB may include a light emitting element ED and a subpixel circuit SPC for driving the light emitting element ED.

Referring to FIG. 3, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off according to a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, may be applied to the at least one subpixel SP. Further, to drive one or more subpixels SP, at least one common driving voltage including a first common driving voltage VDD and a second common driving voltage VSS may be applied to the one or more subpixels SP.

The light emitting element ED may include a first electrode AE, a second electrode CE, and an intermediate layer EL. The intermediate layer EL may be disposed between the first electrode AE and the second electrode CE.

For example, the first electrode AE may be an electrode disposed for each subpixel SP, and the second electrode CE may be an electrode commonly disposed in all or some of a plurality of subpixels SP. For example, the first electrode AE may be an anode electrode, and the second electrode CE may be a cathode electrode. In another example, the first electrode AE may be a cathode electrode, and the second electrode CE may be an anode electrode. Hereinafter, for convenience of explanation, discussions may be provided based on examples where the first electrode AE is an anode electrode, and the second electrode CE is a cathode electrode.

In an example where the light emitting element ED is an organic light emitting diode, the intermediate layer EL may include an emission layer EML, a first common intermediate layer COM1 between the first electrode AE and the emission layer EML, and a second common intermediate layer COM2 between the emission layer EML and the second electrode CE. A layer including the first common intermediate layer COM1 and the second common intermediate layer COM2 may be referred to as a common intermediate layer EL_COM.

In one or more aspects, the emission layer EML may be disposed for each subpixel SP, and the common intermediate layer EL_COM may be commonly disposed across all or some of a plurality of subpixels SP.

The emission layer EML may be disposed in each light emitting area, and the common intermediate layer EL_COM may be disposed commonly across all or some of a plurality of light emitting areas and all or some of a plurality of non-light emitting areas.

In one or more aspects, the first common intermediate layer COM1 may include a hole injection layer HIL and a hole transport layer HTL. The second common intermediate layer COM2 may include an electron transport layer ETL and an electron injection layer EIL.

The hole injection layer HIL can inject holes from the first electrode AE into the hole transport layer HTL, and the hole transport layer HTL can transport holes to the emission layer EML. The electron injection layer can inject electrons from the second electrode CE to the electron transport layer, and the electron transport layer can transport electrons to the emission layer EML.

For example, the second electrode CE may be electrically connected to a second common driving voltage line VSSL. A second common driving voltage VSS may be applied to the second electrode CE through the second common driving voltage line VSSL. The first electrode AE may be electrically connected directly or indirectly (via another transistor) to a first node N1 of a corresponding driving transistor DT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.

Each light emitting element ED may be configured by overlapping of a first electrode AE, an emission layer EML in an intermediate layer EL, and a second electrode CE. A respective light emitting area may be formed by each light emitting element ED. For example, a respective light emitting area of each light emitting element ED may include an area where a first electrode AE, an emission layer EML in an intermediate layer EL, and a second electrode CE overlap with each other.

In one or more aspects, each or at least one of a plurality of light emitting elements ED included in the display panel 110 or the display device 100 may be an organic light emitting diode (OLED), an inorganic light emitting diode (LED), a quantum dot (QD) light emitting element, a micro light emitting diode, a mini light emitting diode, or the like. In the example where each light emitting element ED is an organic light emitting diode (OLED), the intermediate layer EL of a corresponding light emitting element ED may be a layer including an organic material.

The driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD delivered through the first common driving voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes (or electrodes), respectively. However, aspects of the present disclosure are not limited thereto.

The scan transistor ST included in the subpixel circuit SPC illustrated in FIG. 3 may be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL (FIG. 2), and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

The subpixel circuit SPC may have a 2T(Transistor)1C(Capacitor) structure including two transistors (DT and ST) and one capacitor (Cst) as illustrated in FIG. 3. In one or more aspects, the subpixel circuit SPC may further include one or more transistors or one or more capacitors in the 2T1C structure.

For example, the subpixel circuit SPC may have an 8T1C structure including 8 transistors and 1 capacitor. In another example, the subpixel circuit SPC may have an 6T2C structure including 6 transistors and 2 capacitors. In another example, the subpixel circuit SPC may have an 7T1C structure including 7 transistors and 1 capacitor. However, aspects of the present disclosure are not limited to such specific structures.

The types and number of gate signals supplied to a subpixel SP, and/or the types and number of gate lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

Referring to FIG. 3, since circuit elements (e.g., a light emitting element ED such as an organic light emitting diode (OLED) including an organic material in each subpixel SP may be easily damaged by external moisture or oxygen, an encapsulation layer ENCAP may be disposed in the display panel 110 to prevent the external moisture or oxygen from penetrating the circuit elements (e.g., the light emitting element ED).

The encapsulation layer ENCAP may be disposed in various shapes or configurations to prevent light emitting elements ED from contacting moisture or oxygen. For example, the encapsulation layer ENCAP may include two or more layers in which one or more organic layers and one or more inorganic layers are alternately stacked, but aspects of the present disclosure are not limited thereto.

Referring to FIG. 3, in one or more aspects, to sense a touch of a user, the display device 100 may include a touch sensor layer including a plurality of sensor electrodes, a touch driving circuit configured to sense the plurality of sensor electrodes, and a touch controller configured to determine whether a touch is applied or a location of the touch (e.g., touch coordinates) based on the sensing result (e.g., touch sensing data) of the touch driving circuit.

The touch sensor layer may be embedded in the display panel 110. For example, the touch sensor layer may be disposed on the encapsulation layer ENCAP of the display panel 110.

The display panel 110 may include a plurality of touch pads to which the touch driving circuit is electrically connected, and a plurality of touch routing lines for electrically connecting the plurality of sensor electrodes included in the touch sensor layer to the plurality of touch pads to which the touch driving circuit TDC (FIG. 2) is connected.

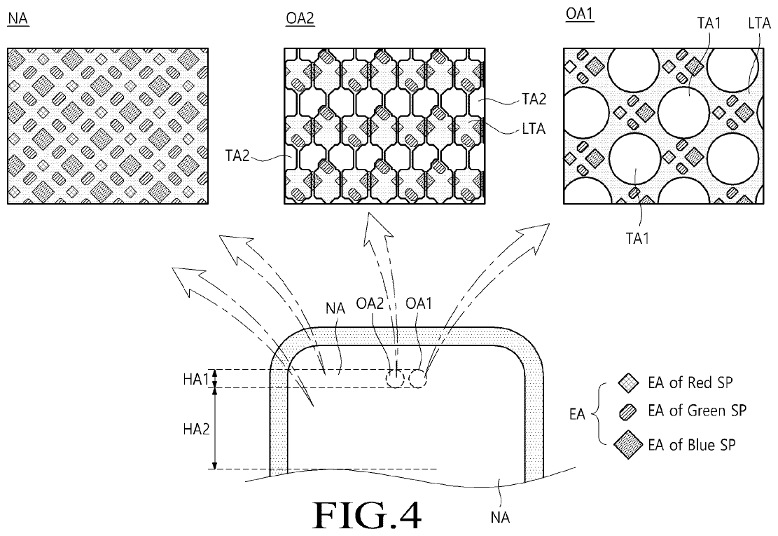

FIG. 4 illustrates the configuration of example three areas (NA, OA1, and OA2) included in the display area DA of the display device 100 (FIG. 1) according to aspects of the present disclosure. In discussions that follow for the configuration of FIG. 4, discussions for features and examples are equal, substantially equal, or similar to the features and examples described with reference to FIGS. 1 to 3 are omitted or briefly described for convenience of description.

Referring to FIG. 4, in one or more example embodiments, a plurality of subpixels SP may be disposed in each of the normal area NA, the first optical area OA1, and the second optical area OA2 included in the display area DA.

The plurality of subpixels SP may include, for example, at least one red subpixel (Red SP) emitting red light, at least one green subpixel (Green SP) emitting green light, and at least one blue subpixel (Blue SP) emitting blue light.

Accordingly, each of the normal area NA, the first optical area OA1, and the second optical area OA2 may include light emitting areas EA of red subpixels (Red SP), and light emitting areas EA of green subpixels (Green SP), and light emitting areas EA of blue subpixels (Blue SP).

Referring to FIG. 4, the normal area NA may not include a light transmissive structure, but include light emitting areas EA.

In this configuration, the optical areas (OA1 and OA2) may be desired to include not only light emitting areas EA, but also light transmissive structures. The optical areas (OA1 and OA2) may include a transmissive area (TA1 and TA2, respectively) and a low-transmissive area LTA. For example, the first optical area OA1 may include at least one first transmissive area TA1 and a low-transmissive area LTA, and the second optical area OA2 may include at least one second transmissive area TA2 and a low-transmissive area LTA.

In each of the optical areas (OA1 and OA2), the low-transmissive area LTA excluding transmissive areas (TA1 or TA2) may include a plurality of light emitting areas EA. Accordingly, in one or more aspects, the first optical area OA1 may include light emitting areas EA and first transmissive areas TA1, and the second optical area OA2 may include light emitting areas EA and second transmissive areas TA2.

In one or more aspects, the low-transmissive areas LTA and the transmissive areas (TA1 and TA2) may be distinct according to whether light is allowed to be transmitted. For example, the low-transmissive areas LTA may be areas allowing light to be transmitted at a low transmittance (or a transmittance less than a predetermined level) or not allowing light to be transmitted, and the transmissive areas (TA1 and TA2) may be areas allowing light to be transmitted or allowing light to be transmitted at a transmittance greater than or equal to the predetermined level.

In one or more aspects, the low-transmissive areas LTA and the transmissive areas (TA1 and TA2) may be also distinct according to whether or not a specific metal layer is included. For example, a second electrode layer CE may be formed in the low-transmissive areas LTA, and the second electrode layer CE may not be formed in the transmissive areas (TA1 and TA2). For example, a light shield layer LSL may be formed in the low-transmissive areas LTA, and the light shield layer LSL may not be formed in the transmissive areas (TA1 and TA2).

In one or more aspects, a plurality of pixel circuits SPC for driving a plurality of light emitting elements ED may be disposed in the low-transmissive areas LTA.

The low-transmissive areas LTA in the optical areas (OA1 and OA2) may be, for example, an area not allowing light to be transmitted. In another example, the low-transmissive areas LTA and the transmissive areas (TA1 and TA2) may be an area allowing light to be transmitted at a low transmittance, for example, a transmittance less than a predetermined level. The transmittance of the low-transmissive areas LTA in the optical areas (OA1 and OA2) may be less than the transmittance of the transmissive areas TA. However, the transmittance of the low-transmissive areas LTA in the optical areas (OA1 and OA2) may be greater than the transmittance of the normal area NA.

According to a light transmissive structure, since the first optical area OA1 includes the first transmissive areas TA1 and the second optical area OA2 includes the second transmissive areas TA2, therefore, the first optical area OA1 and the second optical area OA2 may be areas where light can be transmitted.

In one or more aspects, a transmittance (a degree of transmission) of the first optical area OA1 and a transmittance (a degree of transmission) of the second optical area OA2 may be substantially the same. Herein, being substantially the same may mean the same degree, taking into account a slight difference due to an error in the process.

In this configuration, the first transmissive areas TA1 of the first optical area OA1 and the second transmissive areas TA2 of the second optical area OA2 may have substantially the same shape or size as each other. In one or more aspects, even when the first transmissive areas TA1 of the first optical area OA1 and the second transmissive areas TA2 of the second optical area OA2 have different shapes or sizes, a ratio of the first transmissive areas TA1 to the first optical area OA1 and a ratio of the second transmissive areas TA2 to the second optical area OA2 may be substantially the same as each other.

However, aspects of the present disclosure are not limited thereto. For example, a transmittance (a degree of transmission) of the first optical area OA1 and a transmittance (a degree of transmission) of the second optical area OA2 may be different from each other.

In this configuration, the first transmissive areas TA1 of the first optical area OA1 and the second transmissive areas TA2 of the second optical area OA2 may have different shapes or sizes from each other. In one or more aspects, even when the first transmissive areas TA1 of the first optical area OA1 and the second transmissive areas TA2 of the second optical area OA2 have different shapes or sizes, a ratio of the first transmissive areas TA1 to the first optical area OA1 and a ratio of the second transmissive areas TA2 to the second optical area OA2 may be substantially the same as each other.

In one or more aspects, in the example where the first optical electronic device 11 (FIG. 1) overlapping with the first optical area OA1 is a camera, and the second optical electronic device 12 (FIG. 1) overlapping with the second optical area OA2 is a sensor for detecting images, the camera may need a greater amount of light than the sensor.

Thus, the transmittance (degree of transmission) of the first optical area OA1 may be greater than the transmittance (degree of transmission) of the second optical area OA2.

For example, at least one of the first transmissive areas TA1 of the first optical area OA1 may have a size greater than at least one of the second transmissive areas TA2 of the second optical area OA2. In one or more aspects, even when the first transmissive areas TA1 of the first optical area OA1 and the second transmissive areas TA2 of the second optical area OA2 have substantially the same size as each other, a ratio of the first transmissive areas TA1 to the first optical area OA1 may be greater than a ratio of the second transmissive areas TA2 to the second optical area OA2.

In one or more aspects, as illustrated in FIG. 4, the first transmissive area TA1 of the first optical area OA1 may have a circular shape in a plan view, but the structure of the first transmissive areas TA1 in the plan view according to aspects of the present disclosure is not limited thereto.

For example, the shape of the first transmissive areas TA1 of the first optical area OA1 may have an octagonal shape in the plan view, and in another example, may be formed as an ellipse or a polygon.

In one or more aspects, the area or size of light emitting areas of the first optical area OA1 can be adjusted by changing the shape of the first transmissive areas TA1 and adjusting the transmittance of first transmissive areas TA1.

Hereinafter, for convenience of description, discussions are provided based on an example where a transmittance (a degree of transmission) of the first optical area OA1 is greater than a transmittance (a degree of transmission) of the second optical area OA2.

Further, the transmissive areas (TA1 and TA2) may be referred to as transparent areas and the term transmittance may be referred to as transparency.

Further, in discussions that follow, it is assumed that the first optical area OA1 and the second optical area OA2 are located in an upper edge of the display area DA of the display panel 110 (FIG. 3), and are disposed adjacent to each other a direction from left to right or from right to left.

Referring to FIG. 4, a horizontal display area in which the first optical area OA1 and the second optical area OA2 are disposed may be referred to as a first horizontal display area HA1, and another horizontal display area in which the first optical area OA1 and the second optical area OA2 are not disposed may be referred to as a second horizontal display area HA2.

Referring to FIG. 4, the first horizontal display area HA1 may include a portion of the normal area NA, the first optical area OA1, and the second optical area OA2.

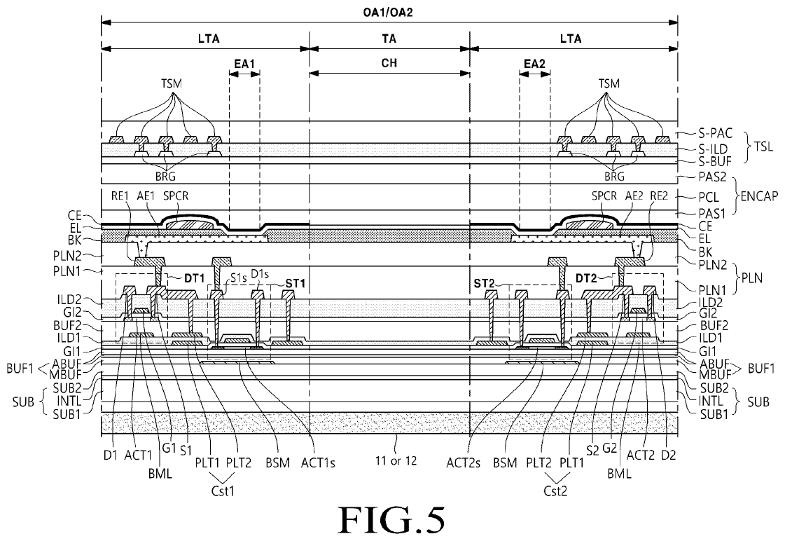

FIG. 5 illustrates an example cross-sectional view of an optical area (e.g., the first optical area OA1 and/or the second optical area OA2) defined in the display panel 110 according to aspects of the present disclosure. In discussions that follow for the configuration of FIG. 5, discussions for features and examples equal, substantially equal, or similar to the features and examples described with reference to FIGS. 1 to 4 are omitted or briefly described for convenience of description.

Referring to FIG. 5, a first light emitting element ED1 and a second light emitting element ED2 may be disposed in the optical area (OA1 and/or OA2). Respective areas where the first light emitting element ED1 and/or the second light emitting element ED2 are disposed is low-transmissive areas LTA, and a transmissive area TA may be disposed between the first light emitting element ED1 and the second light emitting element ED2. For example, the transmissive area TA may be disposed between a first light emitting area EA1 formed by the first light emitting element ED1 and a second light emitting area EA2 formed by the second light emitting element ED2.

Referring to FIG. 5, a pixel circuit SPC may be configured to drive the first light emitting element ED1, and be disposed to overlap with all or a portion of the first light emitting element ED1 in the optical area (OA1 and/or OA2). Another pixel circuit SPC may be configured to drive the second light emitting element ED2, and be disposed to overlap with all or a portion of the second light emitting element ED2 in the optical area (OA1 and/or OA2).

The pixel circuit SPC for driving the first light emitting element ED1 may include a first driving transistor DT1, a first scan transistor ST1, and a first storage capacitor Cst1. The pixel circuit SPC for driving the second light emitting element ED2 may include a second driving transistor DT2, a second scan transistor ST2, and a second storage capacitor Cst2. Since the pixel circuit SPC for driving the first light emitting element ED1 and the pixel circuit SPC for driving the second light emitting element ED2 include substantially the same elements, for convenience of description, discussions are provided by focusing on the pixel circuit SPC for driving the first light emitting element ED1.

Referring to FIG. 5, the display panel 110 (FIG. 3) may include a transistor forming part, a light emitting element forming part, and an encapsulation part in terms of a stack-up structure.

The transistor forming part may include a substrate SUB, a first buffer layer BUF1 on the substrate SUB, and various transistors (DT, ST), a storage capacitor Cst, and various electrodes or signal lines, which are disposed on the first buffer layer BUF.

A lower shield metal BSM may be disposed on the substrate SUB. The lower shield metal BSM may be located under a first active layer ACT1s of the first scan transistor ST1.

The first buffer layer BUF1 may be in the form of a single layer or a multilayer. When the first buffer layer BUF1 is in the form of a multilayer, the first buffer layer BUF1 may include a multi-buffer layer MBUF and an active buffer layer ABUF.

Various transistors (DT1, ST1), at least one storage capacitor Cst, and various electrodes or signal lines may be disposed on the first buffer layer BUF1.

For example, the transistors (DT1, ST1) disposed on the first buffer layer BUF1 may include the same material and be located in one or more layers together. In another example, as illustrated in FIG. 5, among the transistors (DT1, ST1), the first driving transistor DT1 and the first scan transistor ST1 may include different materials and be located in different layers.

The first driving transistor DT1 and the first scan transistor ST1 may be formed in example configurations as follow.

The first scan transistor ST1 may include a first active layer ACT1s, a first gate electrode G1s, a first source electrode S1s, and a first drain electrode D1s.

The first driving transistor DT1 may include a first active layer ACT1, a first gate electrode G1, a first source electrode S1, and a first drain electrode D1.

The first active layer ACT1 of the first driving transistor DT1 may be located higher than the first active layer ACT1s of the first scan transistor ST1.

The first buffer layer BUF1 may be disposed under the first active layer ACT1s of the first scan transistor ST1, and a second buffer layer BUF2 may be disposed under the first active layer ACT1 of the first driving transistor DT1.

For example, the first active layer ACT1s of the first scan transistor ST1 may be located on the first buffer layer BUF1, and the first active layer ACT1 of the first driving transistor DT1 may be located on the second buffer layer BUF2. For example, the second buffer layer BUF2 may be located higher than the first buffer layer BUF1.

The first active layer ACT1s of the first scan transistor ST1 may be located on the first buffer layer BUF1, and a first gate insulating layer GI1 may be disposed on the first active layer ACT1s of the first scan transistor ST1. The first gate electrode G1s of the first scan transistor ST1 may be disposed on the first gate insulating layer GI1, and a first interlayer insulating layer ILD1 may be disposed on the first gate electrode G1s of the first scan transistor ST1.

The first active layer ACT1s of the first scan transistor ST1 may include a first channel region overlapping with the first gate electrode G1s, a first source connection region located on one side of the first channel region, and a first drain connection region located on the other side of the first channel region.

The second buffer layer BUF2 may be disposed on the first interlayer insulating layer ILD1.

The first active layer ACT1 of the first driving transistor DT1 may be disposed on the second buffer layer BUF2, and a second gate insulating layer GI2 may be disposed on the first active layer ACT1. The first gate electrode G1 of the first driving transistor DT1 may be disposed on the second gate insulating layer GI2, and a second interlayer insulating layer ILD2 may be disposed on the first gate electrode G1.

The first active layer ACT1 of the first driving transistor DT1 may include a second channel region overlapping with the first gate electrode G1, a second source connection region located on one side of the second channel region, and a second drain connection region located on the other side of the second channel region.

The first source electrode S1s and the first drain electrode D1s of the first scan transistor ST1 may be disposed on the second interlayer insulating layer ILD2. Further, the first source electrode S1 and the first drain electrode D1 of the first driving transistor DT1 may be disposed on the second interlayer insulating layer ILD2.

The first source electrode S1s and the first drain electrode D1s of the first scan transistor ST1 may be connected to the first source connection region and the first drain connection region of the first active layer ACT1s, respectively, through holes of the second interlayer insulating layer ILD2, the second gate insulating layer GI2, the second buffer layer BUF2, the first interlayer insulating layer ILD1, and the first gate insulating layer GI1.

The first source electrode S1 and the first drain electrode D1 of the first driving transistor DT1 may be connected to the second source connection region and the second drain connection region of the first active layer ACT1, respectively, through holes of the second interlayer insulating layer ILD2 and the second gate insulating layer GI2.

Referring to FIG. 5, the first storage capacitor Cst1 included in the first pixel circuit SPC1 may include the first capacitor electrode PLT1 and the second capacitor electrode PLT2.

The first capacitor electrode PLT1 may be electrically connected to the first gate electrode G1 of the first driving transistor DT1, and the second capacitor electrode PLT2 may be electrically connected to the first source electrode S1 of the first driving transistor DT1.

Referring to FIG. 5, a lower metal BML may be disposed under the first active layer ACT1 of the first driving transistor DT1. The lower metal BML may be overlapped with all or a portion of the first active layer ACT1.

For example, the lower metal BML may be electrically connected to the first gate electrode G1. In another example, the lower metal BML may act as a light shield for blocking light entering from layers thereunder. In this configuration, the lower metal BML may be electrically connected to the first source electrode S1.

The first driving transistor DT1 and the first scan transistor ST1 may be disposed in the low-transmissive area LTA (FIG. 4).

Referring to FIG. 5, the display panel 110 may include at least one planarization layer PLN disposed on the first driving transistor DT1 and the first scan transistor ST1.

For example, referring to FIG. 5, the at least one planarization layer PLN may include a first planarization layer PLN1. The first planarization layer PLN1 may be disposed on the first source electrode S1 and the first drain electrode D1 of the first driving transistor DT1 and the first source electrode S1s and the first drain electrode D1s of the first scan transistor ST1.

Referring to FIG. 5, a first relay electrode RE1 may be disposed on the first planarization layer PLN1.

For example, the first relay electrode RE1 may be an electrode for relaying an electrical connection between the first source electrode S1 of the first driving transistor DT1 and the first electrode AE1 of the first light emitting element ED1. The first relay electrode RE1 may be electrically connected to the first source electrode S1 of the first driving transistor DT1 through a hole of the first planarization layer PLN1.

Referring to FIG. 5, the first relay electrode RE1 may be disposed in the low-transmissive area LTA.

Referring to FIG. 5, the planarization layer PLN disposed in the display panel 110 may further include a second planarization layer PLN2 on the first planarization layer PLN1. For example, the second planarization layer PLN2 may be disposed such that it covers the first relay electrode RE1 located on the first planarization layer PLN1.

FIG. 5 illustrates that the planarization layer PLN includes the first planarization layer PLN1 and the second planarization layer PLN2, but aspects of the present disclosure are not limited thereto. For example, the planarization layer PLN may further include one or more planarization layers.

Referring to FIG. 5, the light emitting element forming part may be located on the second planarization layer PNL2.

Referring to FIG. 5, the light emitting element forming part may include a first light emitting element ED1 and a second light emitting element ED2 disposed on the second planarization layer PNL2. The first light emitting element ED1 and the second light emitting element ED2 may be disposed in the low-transmissive area TLA.

Referring to FIG. 5, the first light emitting element ED1 may be configured in an area where a first electrode AE1, an intermediate layer EL, and a second electrode CE overlap with each other.

Referring to FIG. 5, the first electrode AE1 may be disposed on the second planarization layer PLN2. The first electrode AE1 may be connected to the first relay electrode RE1 through a hole of the second planarization layer PLN2.

Referring to FIG. 5, a bank BK may be disposed on the first electrode AE1. The bank BK may include a plurality of bank holes, and a portion of the first electrode AE1 may be exposed through a corresponding one, or at least one, of the plurality of bank holes. For example, at least one of the plurality of bank holes formed in bank BK may overlap with a portion of the first electrode AE1.

Referring to FIG. 5, the intermediate layer EL may be disposed on the bank BK. The intermediate layer EL may contact respective portions of first electrodes AE (e.g., AE1 and AE2) through the plurality of bank holes.

Referring to FIG. 5, at least one spacer SPCR may be disposed between the intermediate layer EL and the bank BK.

Referring to FIG. 5, the second electrode CE may be disposed on the intermediate layer EL. The cathode electrode CE may not include a plurality of cathode holes CH, or may include a plurality of cathode holes CH. In an example where the cathode electrode CE includes a plurality of cathode holes CH, the plurality of cathode holes CH of the cathode electrode CE may be located to correspond to transmissive areas TA in the optical area (OA1 and/or OA2).

The bank holes of the bank BK may not be overlapped with the cathode holes CH.

An upper surface of the bank BK located under the plurality of cathode holes CH may be flat without being depressed or etched. For example, the bank BK may not be depressed or perforated at places where the cathode holes CH are located. Accordingly, at the places where the cathode holes CH are located, the second planarization layer PLN2 and the first planarization layer PLN1 located under the bank BK may not also be depressed or perforated.

As the upper surface of the bank BK located under the plurality of cathode holes CH is formed to be flat, one or more insulating layers, one or more metal patterns (electrodes, lines, and the like), or an emission layer EL located under the cathode electrode CE may not be damaged by a process of forming the plurality of cathode holes CH in the cathode electrode CE.

The process of forming the plurality of cathode holes CH in the cathode electrode CE is briefly described as follows. After a specific mask pattern is deposited at a location where the plurality of cathode holes CH are to be disposed, a cathode electrode material may be deposited thereon. Accordingly, the cathode electrode material may be deposited only in an area where the specific mask pattern is not present, and thereby, the cathode electrode CE having the plurality of cathode holes CH can be formed. For example, the specific mask pattern may include an organic material. The cathode electrode material may include a magnesium-silver (Mg-Ag) alloy.

After the cathode electrode CE having the plurality of cathode holes CH is formed, the display panel 110 may be in a state where the specific mask pattern is completely removed, or may be in a state where the specific mask pattern remains at least partially.

Referring to FIG. 5, the encapsulation part may be located on the second electrode CE. The encapsulation part may include an encapsulation layer ENCAP disposed on the second electrode CE.

Referring to FIG. 5, the encapsulation layer ENCAP may be a layer for preventing moisture or oxygen from penetrating into the light emitting elements (ED1 and ED2) disposed under the encapsulation layer ENCAP. In particular, the encapsulation layer ENCAP can prevent moisture or oxygen from penetrating into the intermediate layer EL that may include an organic layer. For example, the encapsulation layer ENCAP may be in the form of a single layer or a multilayer.

Referring to FIG. 5, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic layers, and the second encapsulation layer PCL may be an organic layer. Since the second encapsulation layer PCL includes an organic layer, the second encapsulation layer PCL may also serve as a planarization layer.

In one or more aspects, the display panel 110 may include a touch sensor embedded into the display panel 110. In this configuration, the display panel 110 may include a touch sensor layer TSL disposed on the encapsulation layer ENCAP.

Referring to FIG. 5, the touch sensor layer TSL may include touch sensor metals TSM and bridge metals BRG, and may further include insulating layers such as a sensor buffer layer S-BUF, a sensor interlayer insulating layer S-ILD, and a sensor protection layer S-PAC. The sensor interlayer insulating layer S-ILD may be in the form of one or more insulating layers.

The sensor buffer layer S-BUF may be disposed on the encapsulation layer ENCAP. The bridge metals BRG may be disposed on the sensor buffer layer S-BUF, and the sensor interlayer insulating layer S-ILD may be disposed on the bridge metals BRG.

The touch sensor metals TSM may be disposed on the sensor interlayer insulating layer S-ILD. One or more of the touch sensor metals TSM may be connected to corresponding one or more bridge metals BRG through one or more holes of the sensor interlayer insulating layer S-ILD.

Referring to FIG. 5, the touch sensor metals TSM and the bridge metals BRG may be disposed in an optical bezel area OBA. The touch sensor metals TSM and the bridge metals BRG can be disposed not to overlap with the light emitting areas (EA1 and EA2) of the low-transmissive areas LTA.

A plurality of touch sensor metals TSM may form one touch electrode (or one touch electrode line (or array)), and be disposed in a mesh form to be electrically connected to each other. One or more of the touch sensor metals TSM and the remaining one or more touch sensor metals TSM may be electrically connected to each other through at least one bridge metal BRG to form one touch electrode (or one touch electrode line (or array)).

The sensor protection layer S-PAC may be disposed such that it covers the touch sensor metals TSM and the bridge metals BRG.

In one or more aspects, in an example where the touch sensor is embedded into the display panel 110, a corresponding portion of at least one of the touch sensor metals TSM located on the encapsulation layer ENCAP in the display area DA may extend along an outer inclined surface of the encapsulation layer ENCAP, and be electrically connected to a pad located further outwardly than the outer inclined surface of the encapsulation layer ENCAP. For example, the pad may be disposed in the non-display area NDA, and be a metal pattern to which the touch driving circuit TDC is electrically connected.

In one or more aspects, the display panel 110 may include the substrate SUB, the first buffer layer BUF1 disposed between the substrate SUB and the first scan transistor ST1, and the second buffer layer BUF2 disposed between the first scan transistor ST1 and the first driving transistor DT1.

The first active layer ACT1s of the first scan transistor ST1 and the first active layer ACT1 of the first driving transistor DT1 may include different semiconductor materials.

For example, the first active layer ACT1 of the first driving transistor DT1 may include an oxide semiconductor material. For example, the oxide semiconductor material may include indium gallium zinc oxide (IGZO), indium gallium zinc tin oxide (IGZTO), zinc oxide (ZnO), cadmium oxide (CdO), indium oxide (In₂O₃), zinc tin oxide (ZTO), zinc indium tin oxide (ZITO), or the like.

For example, the first active layer ACT1s of the first scan transistor ST1 may include a different semiconductor material from the first active layer ACT1 of the first driving transistor DT1. For example, the first active layer ACT1s of the first scan transistor ST1 may include a silicon-based semiconductor material. For example, the silicon-based semiconductor material may include a low-temperature polycrystalline silicon (LTPS), or the like.

Referring to FIG. 5, a second driving transistor DT2 may include a second active layer ACT2, a second gate electrode G2, a second source electrode S2, and a second drain electrode D2.

The second light emitting element ED2 may be configured in an area where a first electrode AE2, an intermediate layer EL, and a second electrode CE overlap with each other.

The second source electrode S2 of the second driving transistor DT2 may be connected to the first electrode AE2 through a second relay electrode RE2.

A second storage capacitor Cst2 may include a first capacitor electrode PLT1 and a second capacitor electrode PLT2.

The second source electrode S2 of the second driving transistor DT2 may be connected to the second capacitor electrode PLT2 of the second storage capacitor Cst2.

The second gate electrode G2 of the second driving transistor DT2 may be connected to the first capacitor electrode PLT1 of the second storage capacitor Cst2.

An active layer ACT2s of a second scan transistor ST2 may be located on the first buffer layer BUF1 and be located lower than the second active layer ACT2 of the second driving transistor DT2.

A semiconductor material included in the active layer ACT2s of the second scan transistor ST2 may be different from a semiconductor material included in the second active layer ACT2 of the second driving transistor DT2. For example, the semiconductor material included in the second active layer ACT2 of the second driving transistor DT2 may be an oxide semiconductor material, and the semiconductor material included in the active layer ACT2s of the second scan transistor ST2 may be a silicon-based semiconductor material (e.g., a low-temperature polycrystalline silicon (LTPS), or the like).

Referring to FIG. 5, the optical area (OA1 and/or OA2) may overlap with one or more optical electronic devices. The one or more optical electronic devices overlapped with the optical area (OA1 and/or OA2) may be the first optical electronic device 11 and/or the second optical electronic device 12. For example, the one or more optical electronic device may include a camera, an infrared sensor, an ultraviolet sensor, and the like. For example, the one or more optical electronic devices may be one or more devices capable of receiving or detecting visible light to perform a predefined operation, or be one or more devices capable of receiving or detecting light other than visible light (e.g., infrared light, ultraviolet light, and the like) to perform a predefined operation.

Referring to FIG. 5, a cross-sectional structure of the normal area NA may be the same as the cross-sectional structure of the low-transmissive area LTA.

Referring to FIG. 5, two or more light emitting elements ED may be disposed in the optical area (OA1 and/or OA2). For example, two or more light emitting elements ED may be disposed in the low-transmissive area LTA in the optical area (OA1 and/or OA2). In one or more aspects, the transistors (DT, ST) and the storage capacitors Cst may be disposed in the optical area (OA1 and/or OA2). For example, the transistors (DT, ST) and the storage capacitors Cst may be disposed in the low-transmissive area LTA in the optical area (OA1 and/or OA2).

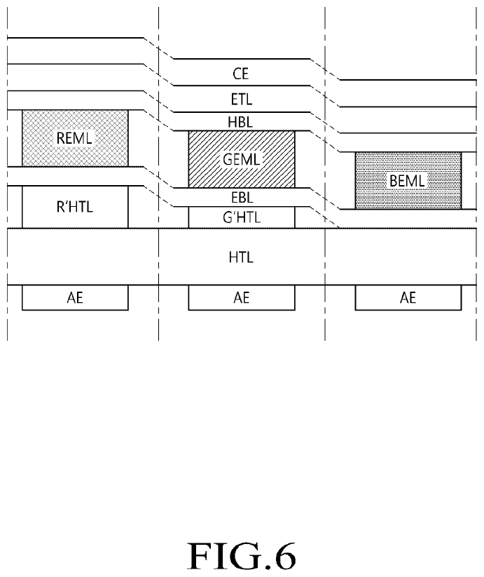

FIG. 6 illustrates an example cross-sectional view of a normal light emitting element. In discussions that follow for the configuration of FIG. 6, discussions for features and examples equal, substantially equal, or similar to the features and examples described with reference to FIGS. 1 to 5 are omitted or briefly described for convenience of description.

Referring to FIG. 6, a display device may include subpixels emitting light of different colors, including a red subpixel Red SP emitting red light, a green subpixel Green SP emitting green light, and a blue subpixel Blue SP emitting blue light (FIG. 4). The red subpixel Red SP may include a light emitting element including a red emission layer REML, the green subpixel Green SP may include a light emitting element including a green emission layer GEML, and the blue subpixel Blue SP may include a light emitting element including a blue emission layer BEML.

Each of the light emitting elements may include a first electrode AE, which is an anode electrode. The first electrode AE may include a conductive material having a relatively large work function value. For example, the first electrode AE may include a transparent or translucent conductive material that can transmit light. For example, the first electrode AE may include a transparent conductive oxide (TCO) selected from the group of indium tin oxide (ITO), indium zinc oxide (IZO), indium tin zinc oxide (ITZO), zinc oxide, and tin oxide. For example, the first electrode AE may include a semi-transmissive conductive material, such as magnesium (Mg), silver (Ag), or an alloy of magnesium (Mg) and silver (Ag).

For example, the first electrode AE may include a metal material having high reflectivity. For example, the first electrode AE may include a highly reflective metal material such as a stacked structure of aluminum and titanium (Ti/Al/Ti), a stacked structure of aluminum and ITO (ITO/Al/ITO), a stacked structure of silver and ITO (ITO/Ag/ITO), a stacked structure of molybdenum titanium (MoTi) and ITO (ITO/MoTi/ITO), a stacked structure of IZO, MoTi and ITO (IZO/MoTi/ITO), an APC alloy, and a stacked structure of an APC alloy and ITO (ITO/APC/ITO). The APC alloy represents an alloy of silver (Ag), palladium (Pd), and copper (Cu).

The light emitting elements may commonly include a hole transport layer HTL on the first electrodes AE. The hole transport layer HTL may be a layer for accelerating and transporting holes from the first electrodes AE to the emission layers. The hole transport layer HTL may be commonly disposed in the subpixels. Although not shown in FIG. 6, the light emitting elements may include a hole injection layer HIL for injecting holes from the first electrodes AE to the emission layers. The hole injection layer may be disposed between the first electrodes AE and the hole transport layer HTL.

The light emitting elements of the subpixels may include hole auxiliary layers (R′HTL, G′HTL, and the like) with different heights, considering wavelengths of light emitted from emission layers and the mobility of holes. Although not shown in FIG. 6, the light emitting element of the blue subpixel Blue SP may also include a hole auxiliary layer. Each hole auxiliary layers can control the mobility of holes from the hole transport layer HTL to a corresponding emission layer and control an optical distance according to wavelengths of light.

The light emitting elements may commonly include an electron blocking layer EBL on the hole transport layer HTL and the hole auxiliary layers (R′HTL, G′HTL, and the like). The electron blocking layer EBL may be a layer for blocking the movement of electrons flowing into the emission layers and enabling the electrons to remain in the emission layers. For example, the electron blocking layer EBL can prevent electrons flowing into the emission layers from moving to the hole transport layer HTL, and thereby prevent electrons and holes from combining in the hole transport layer HTL.

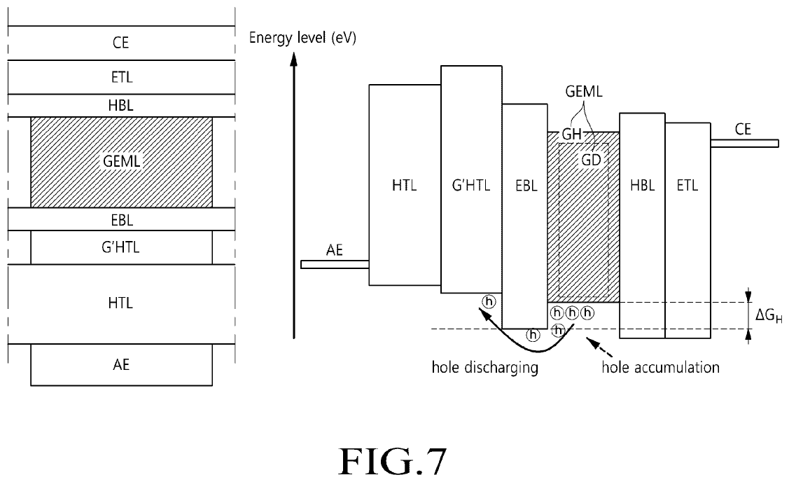

The red emission layer REML, the green emission layer GEML, and the blue emission layer BEML included respectively in the light emitting elements of the subpixels may be disposed on the electron blocking layer EBL. Electrons and holes can combine in each emission layer, and thereby, light of a corresponding color can be emitted. For example, when excitons formed by combining holes injected from the first electrodes AE and electrons injected from a second electrode CE in the emission layer are returned from an excited state (unstable state) to a ground state (stable state), light can be emitted. Each emission layer may include a host (e.g., GH in FIG. 7) and a dopant (e.g., GD in FIG. 7) corresponding to a respective subpixel.

The light emitting elements may commonly include a hole blocking layer HBL on the emission layers (REML, GEML, and BEML). The hole blocking layer HBL may be a layer for blocking the movement of holes flowing into the emission layers and enabling the holes to remain in the emission layers. For example, the hole blocking layer HBL can prevent holes flowing into the emission layers from moving to the electron transport layer ETL, and thereby prevent electrons and holes from combining in the electron transport layer ETL.

The light emitting elements may commonly include an electron transport layer ETL on the hole blocking layer HBL. The electron transport layer ETL may be a layer for accelerating and transporting electrons from the second electrode CE to the emission layers. The electron transport layer ETL may be commonly disposed in the subpixels. Although not shown in FIG. 6, the light emitting elements may include an electron injection layer for injecting electrons from the second electrode CE to the emission layers. The electron injection layer may be disposed between the electron transport layer ETL and the second electrode CE.

The light emitting elements may include the second electrode CE on the electron transport layer ETL. The second electrode CE may include a conductive material having a relatively low work function value. For example, the second electrode may include a metal material having a high reflectivity. For example, the second electrode CE may include a highly reflective metal material such as a stacked structure of aluminum and titanium (Ti/Al/Ti), a stacked structure of aluminum and ITO (ITO/Al/ITO), a stacked structure of silver and ITO (ITO/Ag/ITO), a stacked structure of molybdenum titanium (MoTi) and ITO (ITO/MoTi/ITO), a stacked structure of IZO, MoTi and ITO (IZO/MoTi/ITO), an APC alloy, and a stacked structure of an APC alloy and ITO (ITO/APC/ITO).

For example, the second electrode CE may include a transparent conductive oxide (TCO) selected from the group of ITO, IZO, ITZO, zinc oxide, and tin oxide. For example, the second electrode CE may include a semi-transmissive conductive material such as magnesium (Mg), silver (Ag), or an alloy of magnesium (Mg) and silver (Ag).

FIG. 7 is an example cross-sectional view and energy band diagram for a normal light emitting element. In discussions that follow for the configuration of FIG. 7, discussions for features and examples equal, substantially equal, or similar to the features and examples described with reference to FIGS. 1 to 6 are omitted or briefly described for convenience of description.

Referring to FIG. 7, a light emitting element ED may include a first electrode AE, a hole transport layer HTL, a hole auxiliary layer G′HTL, an electron blocking layer EBL, an emission layer GEML, a hole blocking layer HBL, an electron transport layer ETL, and a second electrode CE. For example, the light emitting element ED illustrated in FIG. 7 may be a green light emitting element emitting green light.

The energy band diagram illustrated in FIG. 7 shows an energy band diagram between the hole transport layer HTL and the emission layer GEML. The upper side of the energy band of a square shape in the energy band diagram of FIG. 7 may mean a lowest unoccupied molecular orbital (LUMO) energy level of each layer, and the lower side thereof may mean a highest occupied molecular orbital (HOMO) energy level of each layer.

Referring to FIG. 7, as the electron blocking layer EBL is disposed between the emission layer GEML and the hole auxiliary layer G′HTL, the emission layer GEML and the hole auxiliary layer G′HTL may be disconnected from each other. For example, the emission layer GEML and the hole auxiliary layer G′HTL may not directly contact each other.

When the light emitting element is turned on, holes injected from the first electrode AE can move through the hole transport layer HTL, the hole auxiliary layer G′HTL, and the electron blocking layer EBL and reach the emission layer GEML, and electrons injected from the second electrode CE can move through the electron transport layer ETL and the hole blocking layer HBL and reach the emission layer GEML. When the light emitting element is turned off, holes and electrons in the emission layer GEML can return to the first electrode AE and the second electrode CE, respectively. Each layer included in the light emitting element may include a material having an appropriate band gap energy so that holes and electrons can be injected and transported to the emission layer GEML.

For example, in a situation where a difference in HOMO energy levels between the hole transport layer HTL, the hole auxiliary layer G′HTL, the electron blocking layer EBL, and the emission layer GEML is not large, when the light emitting element is turned on, holes can move quickly from the hole transport layer HTL to the emission layer GEML, and even when the light emitting element is turned off, holes can move quickly from the emission layer GEML to the hole transport layer HTL.

In this case, when energy at which a difference in HOMO energy levels between the layers is maximum, i.e. HOMO threshold energy ΔHTH is small, a phenomenon where light is emitted in the turn-off state due to leakage current generated in an adjacent subpixel may occur, and thereby, holes may leak.

To prevent this phenomenon, as shown in FIG. 7, the electron blocking layer EBL having a relatively low (deep) HOMO energy level may be disposed adjacent to the emission layer GEML, this causing the magnitude of the HOMO threshold energy to increase.

Here, ΔHTH can be expressed as |H2−H3|, where H2 is the HOMO energy level of the electron blocking layer EBL, and H3 is the HOMO energy level of the hole auxiliary layer G′HTL.

In this structure, when the light emitting element ED changes from the turn-on state to the turn-off state, holes h accumulated in the emission layer GEML cannot move to the first electrode AE relatively quickly, but can move slowly.

That is, although a difference ΔGH between the HOMO energy level of the emission layer GEML and the HOMO energy level of the electron blocking layer is smaller than the HOMO threshold energy ΔHTH, the holes can move relatively slowly when the light emitting element is turned off, and thereby, residual light can remain on the surface of the display device. In particular, sensing sensitivity may be reduced when residual light remains in the optical area (OA1 and/or OA2) where one or more optical electronic devices such as camera, a detection sensor, and the like are placed, as shown in FIG. 5.

Here, ΔGH can be expressed as ΔGH=|H1−H2|, and H1 represents the HOMO energy level of the emission layer GEML.

The energy levels of the energy band diagram shown in FIG. 7 are as follows.

The HOMO energy level H2 of the electron blocking layer EBL may be lower than the HOMO energy level H1 of the emission layer GEML, the HOMO energy level H3 of the hole auxiliary layer G′HTL, and the HOMO energy level H4 of the hole transport layer HTL. The HOMO energy level H1 of the emission layer GEML may be lower than the HOMO energy level H3 of the hole auxiliary layer G′HTL and the HOMO energy level H4 of the hole transport layer HTL. The HOMO energy level H3 of the hole auxiliary layer G′HTL may be lower than the HOMO energy level H4 of the hole transport layer HTL.

A difference ΔGH′ between the HOMO energy level of the emission layer GEML and the HOMO energy level of the hole auxiliary layer can be expressed as |H1−H3|, and a difference ΔGH″ between the HOMO energy level of the emission layer GEML and the HOMO energy level of the hole-transport layer can be expressed as |H1-H4|. The relationship for differences in HOMO energy levels can be expressed by the following Equations 1 and 2.

$$\vert H 1 - H 2 \vert > \vert H 1 - H 4 \vert \qquad [ Equation 1 ]$$

$$\vert H 1 - H 2 \vert > \vert H 1 - H 3 \vert \qquad [ Equation 2 ]$$

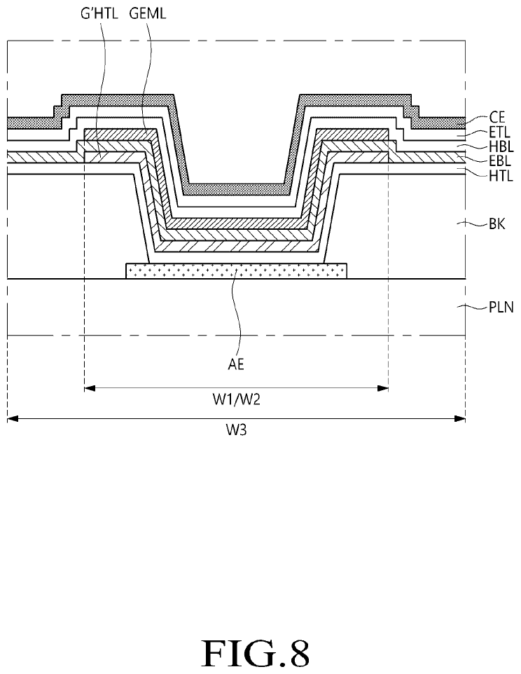

FIG. 8 is an example cross-sectional view of a normal display device to which the light emitting element illustrated in FIG. 7 is applied. In discussions that follow for the configuration of FIG. 8, discussions for features and examples equal, substantially equal, or similar to the features and examples described with reference to FIGS. 1 to 7 are omitted or briefly described for convenience of description.

Referring to FIG. 8, a normal display device may include a planarization layer PLN, a first electrode AE, a bank BK, a hole transport layer HTL, a hole auxiliary layer G′HTL, an electron blocking layer EBL, an emission layer GEML, a hole blocking layer HBL, an electron transport layer ETL, and a second electrode CE.

In an open area of the bank BK, the first electrode AE, the hole transport layer HTL, the hole auxiliary layer G′HTL, the electron blocking layer EBL, the emission layer GEML, the hole blocking layer HBL, the electron transport layer ETL, and the second electrode CE may overlap with, and contact, each other. In this configuration, the open area of the bank BK may serve as a light emitting area.

The hole transport layer HTL, the electron blocking layer EBL, the hole blocking layer HBL, and the electron transport layer ETL may be commonly disposed in two or more of subpixels SP, and may be disposed across two or more light emitting areas and a non-light emitting area. The hole auxiliary layer G′HTL and the emission layer GEML may be individual layers that are patterned and disposed to correspond to in each of subpixels SP, and be disposed in and around the open area of the bank BK, which corresponds the light emitting area and a portion of the non-light emitting area. A width of the emission layer GEML may be represented as W1, a width of the hole auxiliary layer G′HTL may be represented as W2, and in this configuration, the hole auxiliary layer G′HTL and the emission layer GEML may be disposed by a fine mask having a hole of the same size. The electron blocking layer EBL may have the same width as the widths of the hole transport layer HTL, the hole blocking layer, and the electron transport layer ETL, and be formed by an open mask having a hole larger than the hole of the fine mask. The width of the electron blocking layer EBL may be represented as W3.

Referring to FIGS. 7 and 8, when the light emitting element ED changes from a turn-on state to a turn-off state, holes h accumulated in the emission layer GEML can move to the electron blocking layer EBL, the hole auxiliary layer G′HTL, and the hole transport layer HTL in this order and be emitted to the first electrode AE. Therefore, a movement speed of the holes can be relatively slow.

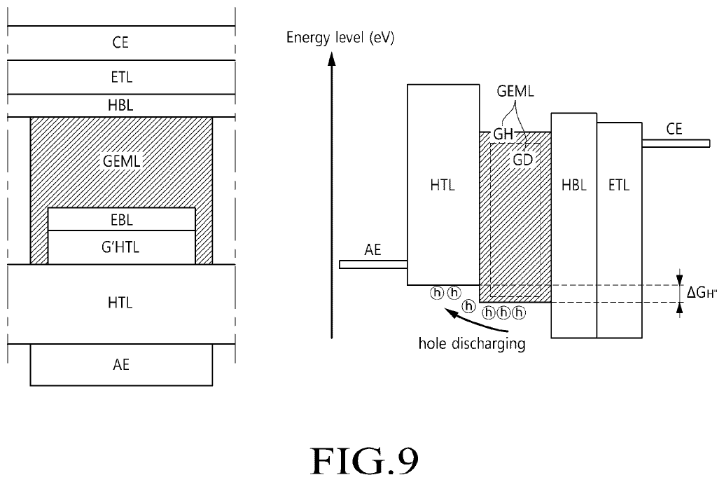

FIG. 9 is an example cross-sectional view and energy band diagram for a light emitting element according to aspects of the present disclosure. In discussions that follow for the configuration of FIG. 7, discussions for features and examples equal, substantially equal, or similar to the features and examples described with reference to FIGS. 1 to 8 are omitted or briefly described for convenience of description.

Referring to FIG. 9, in one or more example embodiments, a light emitting element ED may include an electron blocking layer EBL disposed between an emission layer GEML and a hole auxiliary layer G′HTL. The emission layer GEML may have a structure of directly contacting a hole transport layer HTL. For example, the emission layer GEML may be directly contact the hole transport layer HTL without being disconnected by the electron blocking layer EBL. In this configuration, the hole transport layer HTL, the hole auxiliary layer G′HTL, the electron blocking layer EBL, and the emission layer GEML may be stacked in this order in a light emitting area of the light emitting element ED, and the emission layer GEML and the hole transport layer HTL may be disposed to directly contact each other in a non-light emitting area.

Referring to an energy band diagram illustrated in FIG. 9, the HOMO energy level H1 of the emission layer GEML may be lower than the HOMO energy level H4 of the hole transport layer HTL, and a difference ΔGH” between the HOMO energy level H1 of the emission layer GEML and the HOMO energy level H4 of the hole transport layer may be relatively small. Therefore, when the light emitting element ED changes from a turn-on state to a turn-off state, holes h accumulated in the emission layer GEML can quickly move directly to the hole transport layer HTL.

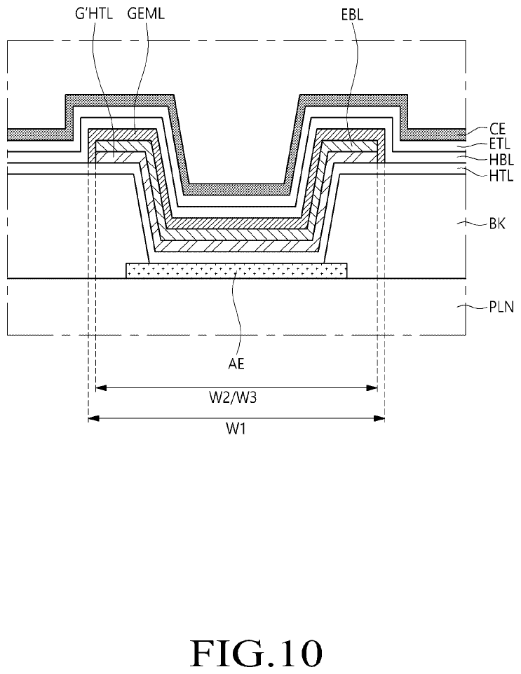

FIG. 10 is an example cross-sectional view of the display device 100 to which the light emitting element ED illustrated in FIG. 9 is applied. In discussions that follow for the configuration of FIG. 10, discussions for features and examples equal, substantially equal, or similar to the features and examples described with reference to FIGS. 1 to 9 are omitted or briefly described for convenience of description.

Referring to FIG. 10, in one or more example embodiments, the display device 100 may include a planarization layer PLN, a first electrode AE, a bank BK, a hole transport layer HTL, a hole auxiliary layer G′HTL, an electron blocking layer EBL, an emission layer GEML, a hole blocking layer HBL, an electron transport layer ETL, and a second electrode CE.

Referring to FIG. 10, a width W1 of the emission layer GEML may be greater than a width W2 of the hole auxiliary layer G′HTL and a width W3 of the electron blocking layer EBL. That is, the electron blocking layer EBL, which is commonly disposed in each subpixel SP, may be patterned and disposed to correspond to each subpixel SP. For example, the width W2 of the hole auxiliary layer G′HTL may have a width of the same size as the width W3 of the electron blocking layer EBL.

Referring to FIG. 10, the emission layer GEML may be disposed to contact the hole transport layer HTL. For example, the emission layer GEML may be disposed to cover the electron blocking layer EBL and contact the hole transport layer HTL. The emission layer GEML may be disposed to cover the upper surface and at least one side surface of the electron blocking layer EBL and contact the hole transport layer HTL. In this configuration, the emission layer GEML may be disposed to cover the at least one side surface of the electron blocking layer EBL and contact the hole transport layer HTL.

Further, the emission layer GEML may be disposed to cover the electron blocking layer EBL and the hole auxiliary layer G′HTL and contact the hole transport layer HTL. For example, the emission layer GEML may be disposed to cover the upper surface and at least one side surface of the electron blocking layer EBL and at least one side surface of the hole auxiliary layer G′HTL and contact the hole transport layer HTL. In this configuration, the emission layer GEML may be disposed to cover respective at least one side surface of the electron blocking layer EBL and the hole auxiliary layer G′HTL and contact the hole transport layer HTL.

The emission layer GEML may contact a portion of the upper surface of the hole transport layer HTL at the upper surface of the bank BK. For example, the emission layer GEML may contact the portion of the upper surface of the hole transport layer HTL in an area around an open area of the bank BK, which is a non-light emitting area.

Referring to FIGS. 9 and 10, the hole transport layer HTL, the hole auxiliary layer G′HTL, the electron blocking layer EBL, and the emission layer GEML may be stacked in this order in the open area of the bank BK, which is a light emitting area, and the emission layer GEML may be disposed to be disconnected from the hole transport layer HTL and the hole auxiliary layer G′HTL in the open area. In the area around the open area of the bank BK, which is the non-light emitting area, the emission layer GEML and the hole transport layer HTL may be disposed to directly contact each other.

By this structure, when the light emitting element ED changes from a turn-on state to a turn-off state, holes h accumulated in the emission layer GEML can directly move to the hole transport layer HTL, and therefore, a movement speed of the holes emitted to the first electrode AE can be quickly controlled.

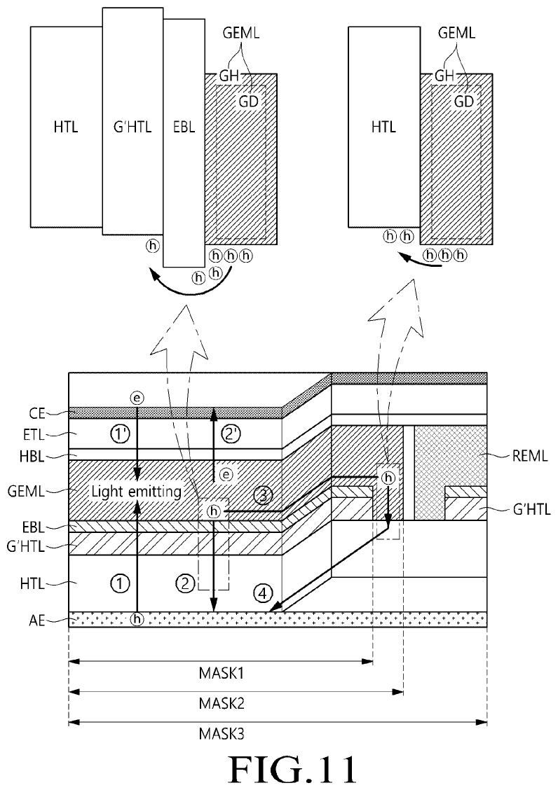

FIG. 11 is an example cross-sectional view for comparing a light emitting element ED according to aspects of the present disclosure with a normal light emitting element. In discussions that follow for the configuration of FIG. 11, discussions for features and examples are equal, substantially equal, or similar to the features and examples described with reference to FIGS. 1 to 10 are omitted or briefly described for convenience of description.

Referring to FIG. 11, in a normal case, when the display device is turned on, holes h can move from a first electrode AE to an emission layer GEML through a first path, and electrons e can move from a second electrode CE to the emission layer GEML through a first' path. Light can be emitted by the combination of the holes h and the electrons e in the emission layer GEML. Thereafter, when the display device is turned off, holes h can move from the emission layer GEML to the first electrode AE through the first path, and electrons e can move from the emission layer GEML to the second electrode CE through the first′ path. That is, in the normal case, when the display device is turned off, the holes h can move slowly from the emission layer GEML to the first electrode AE due to a difference ΔGH between the HOMO energy level of the emission layer GEML and the HOMO energy level of the electron blocking layer.

In contrast, when the display device 100 according to aspects of the present disclosure is turned off, holes h can move from the emission layer GEML to the first electrode AE through a third path and a fourth path. That is, when the display device 100 is turned off, the holes h can move relatively quickly from the emission layer GEML to the first electrode AE due to a difference ΔGH″ between the HOMO energy level of the emission layer GEML and the HOMO energy level of a hole transport layer. The difference ΔGH″ between the HOMO energy level of the emission layer GEML and the HOMO energy level of the hole transport layer may be less than a difference ΔGH between the HOMO energy level of the emission layer GEML and the HOMO energy level of an electron blocking layer. Therefore, a hole movement path through which holes can move quickly can be formed between the emission layer GEML and the hole transport layer HTL, and thereby, holes h can move quickly to the emission layer GEML, the hole transport layer HTL, and the first electrode AE in this order.

Referring to FIG. 11, a hole auxiliary layer G′HTL and the electron blocking layer EBL may be formed using a first mask MASK1, the emission layer GEML may be formed using a second mask MASK2, and other layers may be formed using a third mask MASK3. A hole of the first mask MASK1 may have a smaller size than a hole of the second mask MASK2.

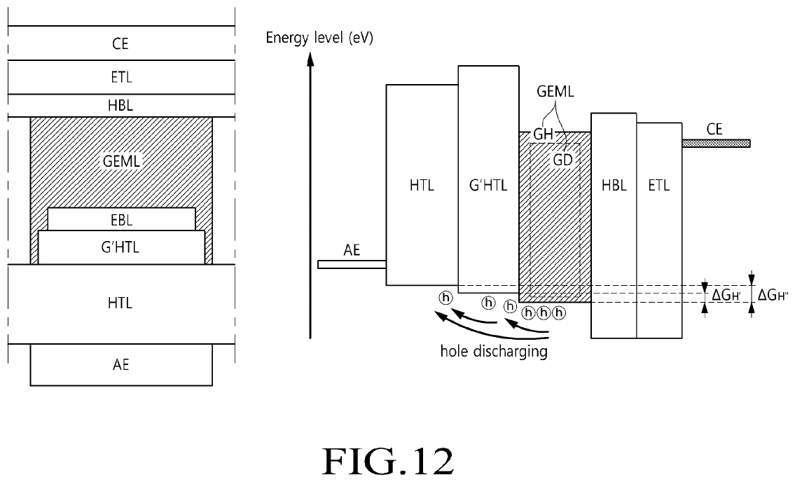

FIG. 12 is an example cross-sectional view and energy band diagram for a light emitting element ED according to aspects of the present disclosure. In discussions that follow for the configuration of FIG. 12, discussions for features and examples equal, substantially equal, or similar to the features and examples described with reference to FIGS. 1 to 11 are omitted or briefly described for convenience of description.

Referring to FIG. 12, in one or more example embodiments, a light emitting element ED may include an electron blocking layer EBL disposed between an emission layer GEML and a hole auxiliary layer G′HTL. The emission layer GEML may have a structure of directly contact a hole transport layer HTL and the hole auxiliary layer G′HTL. For example, the emission layer GEML may be directly contact the hole transport layer HTL and the hole auxiliary layer G′HTL without being disconnected by the electron blocking layer EBL. In this configuration, the hole transport layer HTL, the hole auxiliary layer G′HTL, the electron blocking layer EBL, and the emission layer GEML may be stacked in this order in a light emitting area of the light emitting element ED, and the emission layer GEML may be disposed to directly contact the hole transport layer HTL and the hole auxiliary layer G′HTL in a non-light emitting area.

Referring to the energy band diagram illustrated in FIG. 12, the HOMO energy level H1 of the emission layer GEML may be lower than the HOMO energy level H3 of the hole auxiliary layer G′HTL and the HOMO energy level H4 of the hole transport layer HTL, and the HOMO energy level H3 of the hole auxiliary layer G′HTL may be lower than the HOMO energy level H4 of the hole transport layer HTL. Further, a difference ΔGH′ between the HOMO energy level H1 of the emission layer GEML and the HOMO energy level H3 of the hole auxiliary layer G′HTL and a difference ΔGH″ between the HOMO energy level H1 of the emission layer GEML and the HOMO energy level H4 of the hole-transport layer may be relatively small. Therefore, when the light emitting element ED changes from a turn-on state to a turn-off state, holes h accumulated in the emission layer GEML can quickly move directly to the hole auxiliary layer G′HTL and the hole transport layer HTL.

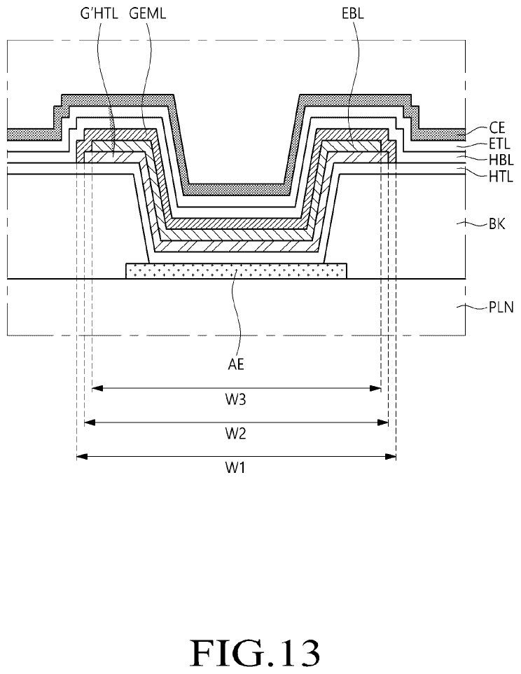

FIG. 13 is an example cross-sectional view of the display device 100 to which the light emitting element ED illustrated in FIG. 12 is applied. In discussions that follow for the configuration of FIG. 13, discussions for features and examples equal, substantially equal, or similar to the features and examples described with reference to FIGS. 1 to 12 are omitted or briefly described for convenience of description.

Referring to FIG. 13, in one or more example embodiments, the display device 100 may include a planarization layer PLN, a first electrode AE, a bank BK, a hole transport layer HTL, a hole auxiliary layer G′HTL, an electron blocking layer EBL, an emission layer GEML, a hole blocking layer HBL, an electron transport layer ETL, and a second electrode CE.

Referring to FIG. 13, a width W1 of the emission layer GEML may be greater than a width W2 of the hole auxiliary layer G′HTL and a width W3 of the electron blocking layer EBL. For example, the width W2 of the hole auxiliary layer G′HTL may have a width greater than the width W3 of the electron blocking layer EBL.

Referring to FIG. 13, the emission layer GEML may be disposed to contact the hole auxiliary layer G′HTL and the hole transport layer HTL. For example, the emission layer GEML may be disposed to cover the electron blocking layer EBL and contact the hole transport layer HTL. The emission layer GEML may be disposed to cover the upper surface and at least one side surface of the electron blocking layer EBL and contact the hole transport layer HTL. In this configuration, the emission layer GEML may be disposed to cover the at least one side surface of the electron blocking layer EBL and contact the hole transport layer HTL.

Further, the emission layer GEML may be disposed to cover the electron blocking layer EBL and the hole auxiliary layer G′HTL and contact the hole transport layer HTL. For example, the emission layer GEML may be disposed to cover the upper surface and at least one side surfaces of the electron blocking layer EBL and a portion of the upper surface and at least one side surface of the hole auxiliary layer G′HTL and contact the hole transport layer HTL. In this configuration, the emission layer GEML may be disposed to cover at least one side surface of the electron blocking layer EBL and at least one side surface of the hole auxiliary layer G′HTL and contact the hole transport layer HTL.

The emission layer GEML may contact the upper surface of the hole transport layer HTL at the upper surface of the bank BK. The emission layer GEML may contact a portion of the upper surface of the hole auxiliary layer G′HTL at the upper surface of the bank BK. For example, the emission layer GEML may contact the upper surface of the hole auxiliary layer G′HTL and the upper surface of the hole transport layer HTL in an area around an open area of the bank BK, which is a non-light emitting area.

Referring to FIGS. 12 and 13, the hole transport layer HTL, the hole auxiliary layer G′HTL, the electron blocking layer EBL, and the emission layer GEML may be stacked in this order in the open area of the bank BK, which is a light emitting area, and the emission layer GEML may be disposed to be disconnected from the hole transport layer HTL and the hole auxiliary layer G′HTL in the open area. In the area around the open area of the bank BK, which is the non-light emitting area, the emission layer GEML may be disposed to directly contact the hole auxiliary layer G′HTL and the hole transport layer HTL.

According to these configurations, when the light emitting element ED changes from a turn-on state to a turn-off state, holes h accumulated in the emission layer GEML can directly move to the hole auxiliary layer G′HTL and the hole transport layer HTL, and therefore, a movement speed of the holes emitted to the first electrode AE can be quickly controlled.

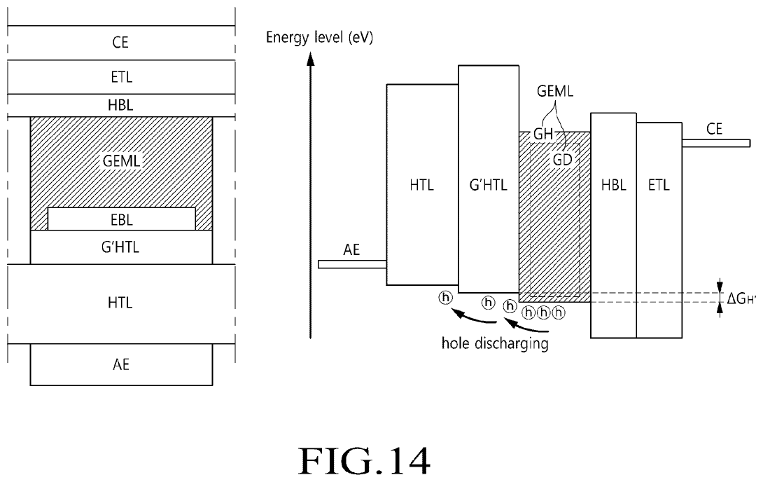

FIG. 14 is an example cross-sectional view and energy band diagram for a light emitting element ED according to aspects of the present disclosure. In discussions that follow for the configuration of FIG. 14, discussions for features and examples are equal, substantially equal, or similar to the features and examples described with reference to FIGS. 1 to 13 are omitted or briefly described for convenience of description.

Referring to FIG. 14, in one or more example embodiments, a light emitting element ED may include an electron blocking layer EBL disposed between an emission layer GEML and a hole auxiliary layer G′HTL. The emission layer GEML may have a structure of directly contacting the hole auxiliary layer G′HTL. For example, the emission layer GEML may be directly contact the hole auxiliary layer G′HTL without being disconnected by the electron blocking layer EBL. In this configuration, the hole transport layer HTL, the hole auxiliary layer G′HTL, the electron blocking layer EBL, and the emission layer GEML may be stacked in this order in a light emitting area of the light emitting element ED, and the emission layer GEML may be disposed to directly contact the hole auxiliary layer G′HTL in a non-light emitting area.

Referring to the energy band diagram illustrated in FIG. 14, the HOMO energy level H1 of the emission layer GEML may be lower than the HOMO energy level H3 of the hole auxiliary layer G′HTL and the HOMO energy level H4 of the hole transport layer HTL, and the HOMO energy level H3 of the hole auxiliary layer G′HTL may be lower than the HOMO energy level H4 of the hole transport layer HTL. Further, a difference ΔGH′ between the HOMO energy level H1 of the emission layer GEML and the HOMO energy level H3 of the hole auxiliary layer G′HTL may be relatively small. Therefore, when the light emitting element ED changes from a turn-on state to a turn-off state, holes h accumulated in the emission layer GEML can quickly move directly to the hole auxiliary layer G′HTL, and the holes moved to the hole auxiliary layer G′HTL can quickly move to the hole transport layer HTL.

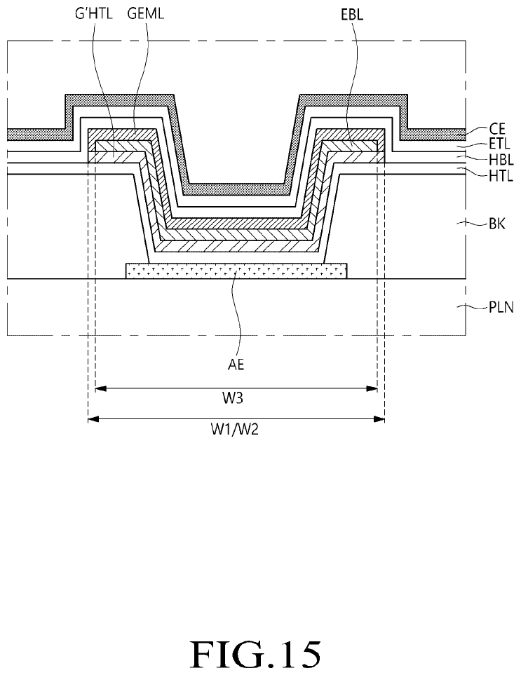

FIG. 15 is an exemplary cross-sectional view of a display device 100 according to aspects of the present disclosure to which the light emitting element illustrated in FIG. 14 is applied. In discussions that follow for the configuration of FIG. 15, discussions for features and examples are equal, substantially equal, or similar to the features and examples described with reference to FIGS. 1 to 14 are omitted or briefly described for convenience of description.

Referring to FIG. 15, in one or more example embodiments, the display device 100 may include a planarization layer PLN, a first electrode AE, a bank BK, a hole transport layer HTL, a hole auxiliary layer G′HTL, an electron blocking layer EBL, an emission layer GEML, a hole blocking layer HBL, an electron transport layer ETL, and a second electrode CE.

Referring to FIG. 15, for example, a width W1 of the emission layer GEML may be same as a width W2 of the hole auxiliary layer G′HTL. For example, the width W1 of the emission layer GEML may be greater than a width W3 of the electron blocking layer EBL.

Referring to FIG. 15, the emission layer GEML may be disposed to contact the hole auxiliary layer G′HTL. For example, the emission layer GEML may be disposed to cover the electron blocking layer EBL and contact the hole auxiliary layer G′HTL. The emission layer GEML may be disposed to cover the upper surface and at least one side surface of the electron blocking layer EBL and contact the hole auxiliary layer G′HTL. In this configuration, the emission layer GEML may be disposed to cover the at least one side surface of the electron blocking layer EBL and contact the hole auxiliary layer G′HTL. The hole auxiliary layer G′HTL may be disposed to directly contact the hole transport layer HTL.

The emission layer GEML may contact the upper surface of the hole auxiliary layer G′HTL at the upper surface of the bank BK. The emission layer GEML may contact a portion of the upper surface of the hole auxiliary layer G′HTL at the upper surface of the bank BK. For example, the emission layer GEML may contact the portion of the upper surface of the hole auxiliary layer G′HTL in an area around an open area of the bank BK, which is a non-light emitting area.

Referring to FIGS. 14 and 15, the hole transport layer HTL, the hole auxiliary layer G′HTL, the electron blocking layer EBL, and the emission layer GEML may be stacked in this order in the open area of the bank BK, which is a light emitting area, and the emission layer GEML may be disposed to be disconnected from the hole transport layer HTL and the hole auxiliary layer G′HTL in the open area. In the area around the open area of the bank BK, which is the non-light emitting area, the emission layer GEML may be disposed to directly contact the hole auxiliary layer G′HTL, and the hole auxiliary layer G′HTL may be disposed to directly contact the hole transport layer HTL.

According to these configurations, when the light emitting element ED changes from a turn-on state to a turn-off state, holes h accumulated in the emission layer GEML can directly move to the hole auxiliary layer G′HTL, and the holes moved to the hole auxiliary layer G′HTL can move to the hole transport layer HTL. Thereby, a movement speed of the holes emitted to the first electrode AE can be rapidly controlled.

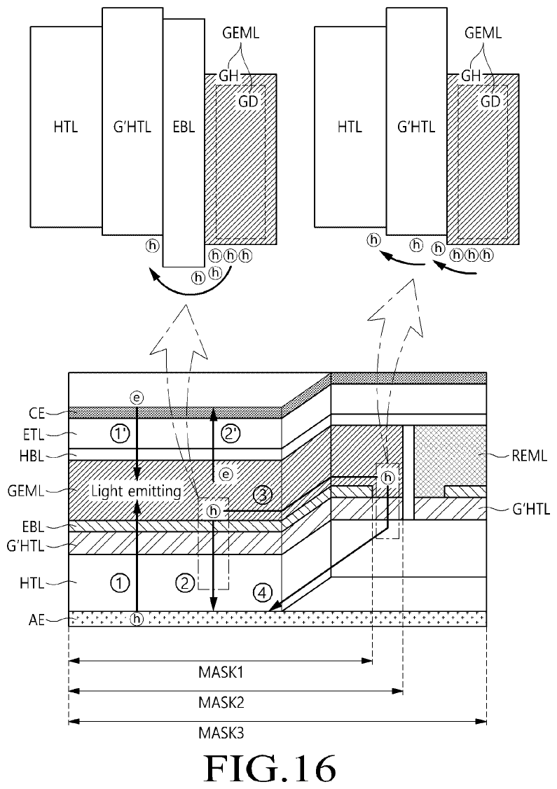

FIG. 16 is an example cross-sectional view for comparing a light emitting element ED according to aspects of the present disclosure with a normal light emitting element. In discussions that follow for the configuration of FIG. 16, discussions for features and examples are equal, substantially equal, or similar to the features and examples described with reference to FIGS. 1 to 15 are omitted or briefly described for convenience of description.

Features related to the movement of holes h in the display device 100 according to aspects of the present disclosure in the configuration of FIG. 16 may be different from those in the configuration of FIG. 11, and therefore, discussions for the configuration of FIG. 16 are provided by focusing on the different features.

Referring to FIG. 16, in the display device 100 according to aspects of the present disclosure, when turned off, holes h can move from an emission layer GEML to a first electrode AE through a third path and a fourth path. That is, when the display device 100 is turned off, the holes h can move relatively quickly from the emission layer GEML to the first electrode AE due to a difference ΔGH″ between the HOMO energy level of the emission layer GEML and the HOMO energy level of a hole auxiliary layer. The difference ΔGH′ between the HOMO energy level of the emission layer GEML and the HOMO energy level of the hole auxiliary layer may be less than a difference ΔGH between the HOMO energy level of the emission layer GEML and the HOMO energy level of an electron blocking layer. Therefore, a hole movement path through which holes can rapidly move can be formed between the emission layer GEML and the hole auxiliary layer G′HTL, and thereby, holes h can rapidly move to the emission layer GEML, the hole auxiliary layer G′HTL, the hole transport layer HTL, and the first electrode AE in this order.

Referring to FIG. 16, the electron blocking layer EBL may be formed using a first mask MASK1. The hole auxiliary layer G′HTL and the emission layer GEML may be formed using a second mask MASK2. Other layers may be formed using a third mask MASK3. A hole of the first mask MASK1 may have a smaller size than a hole of the second mask MASK2.

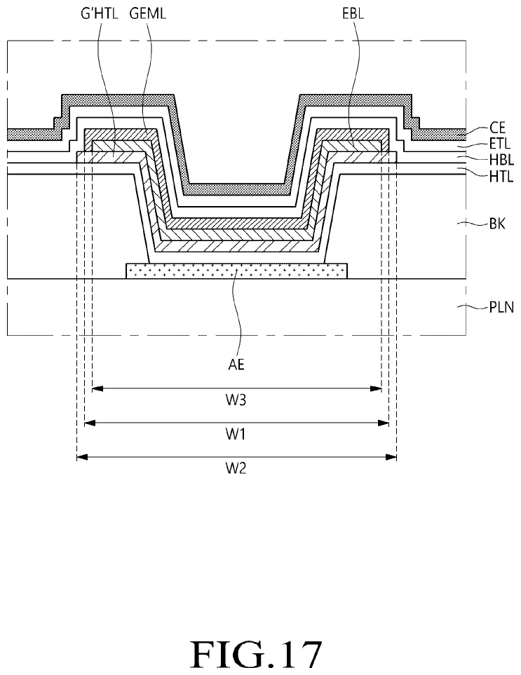

FIG. 17 is an example cross-sectional view of the display device 100 to which the light emitting element ED illustrated in FIG. 14 is applied. In discussions that follow for the configuration of FIG. 17, discussions for features and examples are equal, substantially equal, or similar to the features and examples described with reference to FIGS. 1 to 16 are omitted or briefly described for convenience of description.

Referring to FIG. 17, in one or more example embodiments, the display device 100 may include a planarization layer PLN, a first electrode AE, a bank BK, a hole transport layer HTL, a hole auxiliary layer G′HTL, an electron blocking layer EBL, an emission layer GEML, a hole blocking layer HBL, an electron transport layer ETL, and a second electrode CE.

Referring to FIG. 17, a width W2 of the hole auxiliary layer G′HTL may be greater than a width W1 of the emission layer GEML and a width W3 of the electron blocking layer EBL. For example, the width W1 of the emission layer GEML may be greater than the width W3 of the electron blocking layer EBL.

Referring to FIG. 17, the emission layer GEML may be disposed to contact the hole auxiliary layer G′HTL. For example, the emission layer GEML may be disposed to cover the electron blocking layer EBL and contact the hole auxiliary layer G′HTL. The emission layer GEML may be disposed to cover the upper surface and at least one side surface of the electron blocking layer EBL and contact the hole auxiliary layer G′HTL. The emission layer GEML may be disposed to cover the at least one side surface of the electron blocking layer EBL and contact the hole auxiliary layer G′HTL. The hole auxiliary layer G′HTL may be disposed to directly contact the hole transport layer HTL. In this configuration, the hole blocking layer HBL may be disposed to contact a portion of the upper surface of the hole auxiliary layer G′HTL. For example, the hole blocking layer HBL may be disposed to cover the upper surface and at least one side surface of the emission layer GEML and contact a portion of the upper surface of the electron blocking layer EBL.

The emission layer GEML may contact the upper surface of the hole auxiliary layer G′HTL at the upper surface of the bank BK. The emission layer GEML may contact a portion of the upper surface of the hole auxiliary layer G′HTL at the upper surface of the bank BK. For example, the emission layer GEML may contact the portion of the upper surface of the hole auxiliary layer G′HTL in an area around an open area of the bank BK, which is a non-light emitting area. The hole-blocking layer HBL may be disposed to contact a portion of the upper surface of the hole auxiliary layer G′HTL in the area around the open area of the bank BK, which is the non-light emitting area.

Referring to FIGS. 14 and 17, the hole transport layer HTL, the hole auxiliary layer G′HTL, the electron blocking layer EBL, and the emission layer GEML may be stacked in this order in the open area of the bank BK, which is a light emitting area, and the emission layer GEML may be disposed to be disconnected from the hole transport layer HTL and the hole auxiliary layer G′HTL in the open area. In the area around the open area of the bank BK, which is the non-light emitting area, the emission layer GEML may be disposed to directly contact the hole auxiliary layer G′HTL, and the hole auxiliary layer G′HTL may be disposed to directly contact the hole transport layer HTL.

According to these configurations, when the light emitting element ED changes from a turn-on state to a turn-off state, holes h accumulated in the emission layer GEML can directly move to the hole auxiliary layer G′HTL, and the holes moved to the hole auxiliary layer G′HTL can move to the hole transport layer HTL. Thereby, a movement speed of the holes emitted to the first electrode AE can be rapidly controlled.

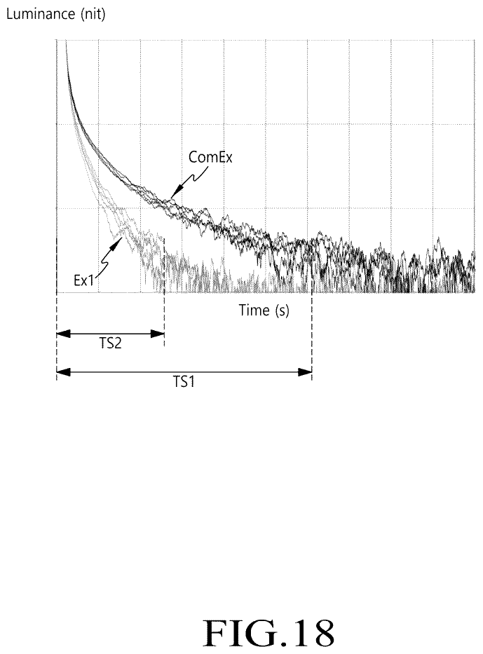

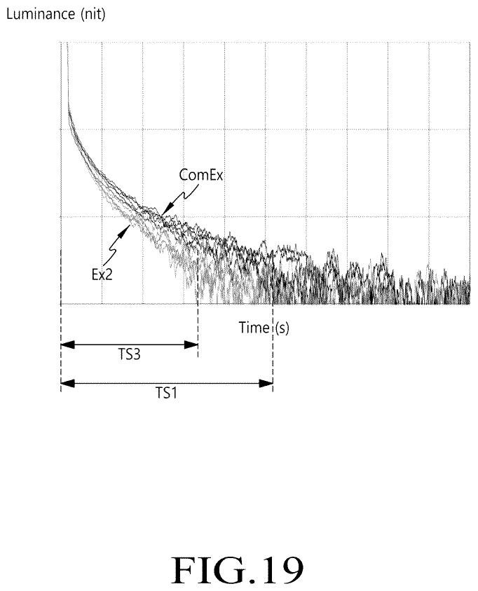

FIGS. 18 and 19 are graphs illustrating example characteristics of luminance and turn-off in the display device 100 according to aspects of the present disclosure and a normal display device. In discussions that follow for the configuration of FIGS. 18 and 19, discussions for features and examples equal, substantially equal, or similar to the features and examples described with reference to FIGS. 1 to 17 are omitted or briefly described for convenience of description.

In the graph of FIG. 18, Comparative Example ComEx represents luminance over time measured from the display device having the structure illustrated in FIG. 8, and Embodiment 1 Ex1 represents luminance over time measured from the display device 100 according to aspects of the present disclosure illustrated in FIG. 10.

Referring to FIG. 18, when the display device is turned off from a turn-on state, it can be seen that the respective luminance of Comparative Example ComEx and Embodiment 1 Ex1 decrease over time. In the case of Comparative Example ComEx, it can be confirmed that the luminance continuously decreases even after a time TS1 when the luminance first reaches a minimum value, and the luminance reaches the minimum value wholly. In contrast, in the case of Embodiment 1, it can be confirmed that a time TS2 when the luminance first reaches a minimum value is shorter than the time TS1 of Comparative Example ComEx, and thereafter, a time until the luminance reaches the minimum value wholly is also shorter. This means that holes accumulated in the emission layer in Embodiment 1 Ex1 move directly to the hole transport layer and are quickly emitted to the first electrode.

In the graph of FIG. 19, Comparative Example ComEx represents luminance over time measured from the display device having the structure illustrated in FIG. 8, and Embodiment 2 Ex2 represents luminance over time measured from the display device 100 according to aspects of the present disclosure illustrated in FIG. 15.

Referring to FIG. 19, when the display device is turned off from a turn-on state, it can be confirmed that in the case of Embodiment 2Ex2, a time TS3 when the luminance of Embodiment 2 Ex2 first reaches a minimum value is shorter than the time TS1 of the Comparative Example ComEx, and thereafter, a time until the luminance to reach the minimum value wholly is also shorter. In particular, in the case of Example 2Ex2, it can be confirmed that a difference ΔGH′ between the HOMO energy level of the emission layer GEML and the HOMO energy level of the hole auxiliary layer has a smaller value than a difference ΔGH″ between the HOMO energy level of the emission layer GEML and the HOMO energy level of the hole-transport layer, and therefore, a width (or degree) at which the luminance decrease in an initial period decrease is increased. This means that in Example 2Ex2, holes accumulated in the emission layer move directly to the hole auxiliary layer and are quickly emitted to the hole transport layer and the first electrode.

The display device 100 according to example, aspects, and embodiments of the present disclosure may be described as follows.

The display device 100 according to example embodiments of the present disclosure may include a plurality of light emitting elements disposed on a substrate. In one or more aspects, at least one of the plurality of light emitting elements may include a first electrode disposed on the substrate, a hole transport layer disposed on the first electrode, an electron blocking layer disposed on the hole transport layer, an emission layer disposed on the electron blocking layer and having a width greater than the electron blocking layer, and a second electrode disposed on the emission layer.

In one or more aspects, in the display device, a highest occupied molecular orbital (HOMO) energy level of the electron blocking layer may be less than a HOMO energy level of the emission layer.

In one or more aspects, in the display device, the following Equation 1 is satisfied,

$$\vert H 1 - H 2 \vert > \vert H 1 - H 4 \vert , \qquad [ Equation 1 ]$$

wherein H1 is the HOMO energy level of the emission layer, H2 is the HOMO energy level of the electron blocking layer, and H4 is a HOMO energy level of the hole transport layer.

In one or more aspects, in the display device, the emission layer may be disposed to cover the electron blocking layer and contact the hole transport layer.

In one or more aspects, in the display device, wherein the light emitting element may further include a hole auxiliary layer disposed between the hole transport layer and the electron blocking layer. In one or more aspects, the emission layer may be disposed to cover the electron blocking layer and the hole auxiliary layer and contact the hole transport layer.

In one or more aspects, in the display device, a width of the hole auxiliary layer may be the same as a width of the electron blocking layer.

In one or more aspects, in the display device, the emission layer may be disposed to cover an upper surface and at least one side surface of the electron blocking layer and at least one side surface of the hole auxiliary layer and contact the hole transport layer.

In one or more aspects, in the display device, a width of the emission layer may be greater than a width of the hole auxiliary layer, and the width of the hole auxiliary layer may be greater than a width of the electron blocking layer.

In one or more aspects, in the display device, the emission layer may be disposed to cover an upper surface and at least one side surface of the electron blocking layer and a portion of an upper surface and at least one side surface of the hole auxiliary layer and contact the hole transport layer.

In one or more aspects, in the display device, the following Equation 2 is satisfied,

$$\vert H 1 - H 2 \vert > \vert H 1 - H 4 \vert , \qquad [ Equation 2 ]$$

wherein H1 is the HOMO energy level of the emission layer, H2 is the HOMO energy level of the electron blocking layer, and H3 is a HOMO energy level of the hole auxiliary layer.

In one or more aspects, in the display device, the light emitting element may further include a hole auxiliary layer disposed between the hole transport layer and the electron blocking layer. In one or more aspects, a width of the hole auxiliary layer may be greater than a width of the electron blocking layer.

In one or more aspects, in the display device, the emission layer may be disposed to cover the electron blocking layer and contact the hole auxiliary layer.

In one or more aspects, in the display device, the width of the hole auxiliary layer may be the same as a width of the emission layer.

In one or more aspects, in the display device, the emission layer may be disposed to cover an upper surface and at least one side surface of the electron blocking layer and contact at least a portion of an upper surface of the hole auxiliary layer.

In one or more aspects, in the display device, a width of the hole auxiliary layer may be greater than a width of the emission layer.

In one or more aspects, in the display device, the emission layer may be disposed to cover an upper surface and at least one side surface of the electron blocking layer and contact an inner portion of at least one end of an upper surface of the hole auxiliary layer.

In one or more aspects, in the display device, the display device may further include a hole blocking layer disposed on the emission layer. In one or more aspects, the hole blocking layer may be disposed to cover the emission layer and contact the hole transport layer.

In one or more aspects, in the display device, the substrate may include a normal area having a first resolution, and an optical area having a resolution lower than the first resolution. In one or more aspects, the display device may include an optical electronic device overlapped with the optical area and disposed under the substrate.

In one or more aspects, in the display device, the at least one light emitting element may be disposed in the normal area.

In one or more aspects, in the display device, the at least one light emitting element may be disposed in the optical area.

According to the one or more aspects described herein, a display device may be provided that includes a light transmissive structure capable of enabling at least one optical electronic device disposed under, or at a lower portion of, a display panel to normally receive light (e.g., visible light, infrared light, ultraviolet light, or the like) while not being exposed in the front of the display device.

According to the one or more aspects described herein, a display device may be provided that is capable of enabling a full-screen display to be implemented by using a whole display area of a display panel as a display screen by including a structure at least one optical electronic device is disposed to be overlapped with the display area while being located under the display area.

According to the one or more aspects described herein, a display device may be provided that is capable of preventing or reducing the presence of residual light by including a structure where a hole movement path is formed in a light emitting element.

According to the one or more aspects described herein, a display device may be provided that is capable of preventing or reducing malfunction of one or more optical sensors by including a structure where a hole movement path is formed in a light emitting element.

According to the one or more aspects described herein, a display device may be provided that is capable of improving the sensing efficiency of one or more optical sensors by external light by including a structure where a hole movement path is formed in a light emitting element.

According to the one or more aspects described herein, a display device may be provided that is capable of improving the reliability of light emitting elements by reducing the degradation of luminance in a display area and the reduction of lifetime of the light emitting elements.

According to the one or more aspects described herein, a display device may be provided that is capable of enabling high efficiency, improving lifetime and consuming low power by reducing the degradation of luminance in a display area and the reduction of lifetime of light emitting elements.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical features of the present disclosure.

What is claimed is:

1. A display device comprising:
a plurality of light emitting elements disposed on a substrate,
wherein at least one of the plurality of light emitting elements comprises:
a first electrode disposed on the substrate;
a hole transport layer disposed on the first electrode;
an electron blocking layer disposed on the hole transport layer;
an emission layer disposed on the electron blocking layer, wherein the emission layer has a width greater than a width of the electron blocking layer; and
a second electrode disposed on the emission layer.

2. The display device of claim 1, wherein a highest occupied molecular orbital (HOMO) energy level of the electron blocking layer is less than a highest occupied molecular orbital (HOMO) energy level of the emission layer.

3. The display device of claim 2, wherein in the display device, Equation 1 is satisfied,
$$\vert H 1 - H 2 \vert > \vert H 1 - H 4 \vert \qquad [ Equation 1 ]$$
wherein H1 is the highest occupied molecular orbital (HOMO) energy level of the emission layer, H2 is the highest occupied molecular orbital (HOMO) energy level of the electron blocking layer, and H4 is a highest occupied molecular orbital (HOMO) energy level of the hole transport layer.

4. The display device of claim 1, wherein the emission layer is disposed to cover the electron blocking layer and to contact the hole transport layer.

5. The display device of claim 4, wherein the at least one of the plurality of light emitting elements further comprises a hole auxiliary layer disposed between the hole transport layer and the electron blocking layer, and
wherein the emission layer is disposed to cover the electron blocking layer and the hole auxiliary layer and to contact the hole transport layer.

6. The display device of claim 5, wherein a width of the hole auxiliary layer is same as a width of the electron blocking layer.

7. The display device of claim 6, wherein the emission layer is disposed to cover an upper surface and at least one side surface of the electron blocking layer and at least one side surface of the hole auxiliary layer and to contact the hole transport layer.

8. The display device of claim 5, wherein a width of the emission layer is greater than the width of the hole auxiliary layer, and the width of the hole auxiliary layer is greater than the width of the electron blocking layer.

9. The display device of claim 8, wherein the emission layer is disposed to cover an upper surface and at least one side surface of the electron blocking layer and a portion of an upper surface and at least one side surface of the hole auxiliary layer and to contact the hole transport layer.

10. The display device of claim 5, wherein in the display device, Equation 2 is satisfied,
$$\vert H 1 - H 2 \vert > \vert H 1 - H 3 \vert \qquad [ Equation 2 ]$$
wherein H1 is the highest occupied molecular orbital (HOMO) energy level of the emission layer, H2 is the highest occupied molecular orbital (HOMO) energy level of the electron blocking layer, and H3 is a highest occupied molecular orbital (HOMO) energy level of the hole auxiliary layer.

11. The display device of claim 1, wherein the at least one of the plurality of light emitting elements further comprises a hole auxiliary layer disposed between the hole transport layer and the electron blocking layer, and wherein a width of the hole auxiliary layer is greater than a width of the electron blocking layer.

12. The display device of claim 11, wherein the emission layer is disposed to cover the electron blocking layer and to contact the hole auxiliary layer.

13. The display device of claim 11, wherein the width of the hole auxiliary layer is same as the width of the emission layer.

14. The display device of claim 13, wherein the emission layer is disposed to cover an upper surface and at least one side surface of the electron blocking layer and to contact at least a portion of an upper surface of the hole auxiliary layer.

15. The display device of claim 11, wherein the width of the hole auxiliary layer is greater than the width of the emission layer.

16. The display device of claim 15, wherein the emission layer is disposed to cover an upper surface and at least one side surface of the electron blocking layer and to contact an inner portion of at least one end of an upper surface of the hole auxiliary layer.

17. The display device of claim 1, further comprising a hole blocking layer disposed on the emission layer,
wherein the hole blocking layer is disposed to cover the emission layer and to contact the hole transport layer.

18. The display device of claim 1, wherein the substrate comprises:
a normal area having a first resolution;
an optical area having a resolution lower than the first resolution and
an optical electronic device, wherein the optical electronic device is overlapped with the optical area and is disposed under the substrate.

19. The display device of claim 18, wherein the at least one of the plurality of light emitting elements is disposed in the normal area.

20. The display device of claim 18, wherein the at least one of the plurality of light emitting elements is disposed in the optical area.
